(19) United States
(12) Patent Application Publication
(10) Pub. No.: US 2006/0180847 A1
(43) Pub. Date: Aug. 17, 2006

(54) Two-bit non-volatile memory devices including independently-controllable gate electrodes and methods for fabricating the same

(75) Inventors: Ki-Tae Park, Gyeonggi-do (KR); Jung-Dal Choi, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd., Gyeonggi-do (KR)

(21) Appl. No.: 11/353,726

(22) Filed: Feb. 14, 2006

(30) Foreign Application Priority Data
Feb. 14, 2005 (KR) 10-2005-0011978

(51) Int. Cl. H01L 29/76

(52) U.S. Cl. 257/314

(57) ABSTRACT

A non-volatile integrated circuit memory device includes a substrate including first and second source/drain regions therein and a channel region therebetween, a first memory cell on the channel region adjacent the first source/drain region, and a second memory cell on the channel region adjacent the second source/drain region. The first memory cell includes a first conductive gate on the channel region and a first multi-layered charge storage structure therebetween. Similarly, the second memory cell includes a second conductive gate on the channel region and a second multi-layered charge storage structure therebetween. A single-layer insulating layer on the channel region extends between the first and second memory cells along sidewalls thereof. The single-layer insulating layer may not include a charge-trapping layer, and may separate the first and second conductive gates by a distance of less than a thickness of the first multi-layered charge storage structure. Related fabrication methods are also discussed.

### CROSS-REFERENCE TO RELATED APPLICATIONS

The present application claims priority under 35 U.S.C. §119 from Korean Patent Application No. 10-2005-0011978, filed on Feb. 14, 2005, in the Korean Intellectual Property Office, the disclosure of which is hereby incorporated by reference herein in its entirety.

### FIELD OF THE INVENTION

The present invention relates to semiconductor devices, and more particularly, to non-volatile memory devices and methods for fabricating the same.

### BACKGROUND OF THE INVENTION

Generally, non-volatile memory devices, such as eraseable programmable read only memory (EPROM), electrically eraseable programmable read only memory (EEPROM), flash EEPROM, and the like, may retain stored data even without power supplied thereto.

In comparison with conventional non-volatile memory devices including a floating gate, non-volatile memory devices using nonconductors (which may enable charges to be trapped locally), may offer advantages such as simpler manufacturing processes and/or higher degrees of integration than conventional non-volatile memory devices, while using similar photolithographic etching technology. For example, a nonconductor which can locally trap charges may employ a silicon nitride layer. More particularly, an oxide-nitride-oxide multilayer (i.e., an ONO layer), where a silicon nitride layer is sandwiched between two oxide layers, may be used as a charge-trapping layer in a non-volatile memory device.

FIG. 1A is a cross-sectional view of a first conventional non-volatile memory device using an ONO layer, which is disclosed in U.S. Pat. No. 5,168,334 to Mitchell et al. FIG. 1B is an equivalent circuit diagram illustrating the non-volatile memory device of FIG. 1A. Referring to FIGS. 1A and 1B, the conventional memory device includes an ONO layer 3 and a polysilicon 5 stacked on a substrate 1 in sequence. The ONO layer 3 includes an oxide layer 2a, a nitride layer 2b, and an oxide layer 2c formed over a channel between source/drain regions 7 which are formed in the semiconductor substrate 1. However, as illustrated in FIG. 1B, the memory device is a single-bit non-volatile memory cell 6, which may represent one of two states (i.e., logic levels 0 and 1) according to whether or not charges are trapped in the nitride layer 2b of the ONO layer 3.

As such, memory devices with increased capacity for storing information have been developed. More particularly, various types of two bit non-volatile memory devices have been developed. FIG. 2A is a cross-sectional view illustrating a second conventional memory device, which is disclosed in U.S. Pat. No. 5,768,192 to Eitan, and FIG. 2B is an equivalent circuit diagram illustrating the second conventional memory device of FIG. 2A. Referring to FIGS. 2A and 2B, unlike the conventional memory device of FIG. 1A, there are two charge-trapping regions 24L and 24R in the nitride layer 22b of an ONO layer 23. Thus, charges are selectively and independently stored at the charge-trapping regions 24L and 24R of the nitride layer 22b. By applying an appropriate voltage to a gate 25, source/drain regions 27, and a substrate 21, respectively, the charges may be selectively and independently injected into the charge-trapping regions 24L and 24R near each of the source/drain regions 27.

In FIG. 2A, the charge-trapping regions 24L and 24R (to which the charges may be injected) are depicted as a shaded portion. The memory device of FIG. 2A, as illustrated in the equivalent circuit diagram of FIG. 2B, may be regarded as three transistors 26L, 26C, and 26R, where a channel between the source/drain regions 27 may include three channel regions Ls1, Lc and Ls2 connected to each other in series. The threshold voltage of the memory transistor 26L (having the channel region Ls1) and the memory transistor 26R (having the channel region Ls2) may be varied based on the amount of charges injected into the respective charge-trapping regions 24L and 24R. As such, the memory transistors 26L and 26R may be regarded as short channel devices having a channel width of 50 nm or less. The memory device of FIG. 2A may offer advantages such as reduced manufacturing costs, because it has a relatively simple structure, as similar to the conventional memory device of FIG. 1A. However, the three transistors 26L, 26C and 26R may be controlled through only one gate 25, thereby limiting the applied operational voltage. As a result, a sensing margin property, which may be represented as a signal difference between stored bit information of the memory device (i.e., logic level 0 and logic level 1), may be degraded.

Furthermore, as the device size is reduced to provide higher integration, the distance between the source and the drain may become closer and closer. More specifically, referring to FIG. 2A, the two charge-trapping regions 24L and 24R may become closer to each other. Since the charges stored in the nitride thin film 22b of an insulator may also move little by little into the channel of the memory device by lateral diffusion, the effective distance between the two charge-trapping regions 24L and 24R may become narrower and narrower. As such, the two charge-trapping regions 24L and 24R may effectively become physically connected to each other, so that it may impossible to distinguish two different bits of information. This may pose serious problems with regard to scaling down the sizes of memory devices while providing reduced price and greater density.

FIG. 3A is a cross-sectional view illustrating another conventional memory device, which is disclosed in U.S. Pat. No. 6,706,599 to Sadd et al, and FIG. 3B is an equivalent circuit diagram illustrating the third conventional memory device of FIG. 3A. Referring to FIG. 3A, unlike the conventional memory device shown in FIG. 2A, portions of a nitride layer 32b of an ONO layer 33 (which can stores charges therein) are physically separated from each other. Accordingly, even as the memory device becomes smaller and smaller, the two different charge-trapping regions 34L and 34R are not electrically connected to each other, due to an insulating layer 32a therebetween. While such a conventional memory device may be scaled down to a greater extent than the device of FIG. 2A, the three transistors 36L, 36C and 36R may still be controlled through only one gate 35. As such, the applied operational voltage may be limited, and thus, a sensing margin property, which may be represented as a signal difference between stored bit information of the memory device (i.e., logic level 0 and logic level 1), may be degraded.

FIG. 4A is a cross-sectional view illustrating still another conventional memory device, which is disclosed in U.S. Pat. No. 6,248,633 to Ogura et al., and FIG. 4B is an equivalent circuit diagram illustrating the fourth conventional memory device of FIG. 4A. This conventional memory device includes control gates 45L and 45R on both sidewalls of a select gate 40 for independently controlling transistors, and an ONO layer 43 including charge-trapping regions 44L and 44R. The ONO layer 43 is disposed under each of the control gates 45L and 45R. The select gate 49 between the control gates 45L and 45R is electrically isolated from a substrate 41 by a gate oxide layer 42g, and is also electrically isolated from the control gates 45L and 45R by an oxide layer 42s. Since the control gates 45L and 45R are independently formed over each of the charge-trapping regions 44L and 44R and the select gate 49 can be also separately controlled, it is possible to apply optimized voltages to each gate. Accordingly, a sensing margin property, which may be represented as a signal difference between stored bit information of the memory device, may be improved in comparison with the conventional non-volatile memory devices of FIGS. 1 to 3. However, to control the three gates 45L, 45R, and 49, peripheral circuitry may become relatively complex. Moreover, since the select gate 49 may not be necessarily needed in all types of memory devices, it may be more difficult for such a memory device to be scaled down.

### SUMMARY OF THE INVENTION

According to some embodiments of the present invention, a non-volatile integrated circuit memory device may include a substrate including first and second source/drain regions therein and a channel region therebetween, a first memory cell on the channel region adjacent the first source/drain region, a second memory cell on the channel region adjacent the second source/drain region, and a single-layer insulating layer on the channel region extending between the first and second memory cells along sidewalls thereof. The first memory cell may include a first conductive gate on the channel region and a first multi-layered charge storage structure therebetween. Similarly, the second memory cell may include a second conductive gate on the channel region and a second multi-layered charge storage structure therebetween. The single-layer insulating layer may separate the first and second conductive gates by a distance of less than a thickness of the first multi-layered charge storage structure.

In some embodiments, a portion of the single-layer insulating layer between the first and second multi-layered charge storage structures may have a dielectric strength greater than a portion thereof between the first and second conductive gates. The single-layer insulating layer may not include a charge-trapping layer.

In other embodiments, the channel region may include first, second, and third portions. The first portion may be adjacent the first multi-layered charge storage structure, and may be configured to be controlled by the first conductive gate. The second portion may be adjacent the second multi-layered charge storage structure, and may be configured to be controlled by the second conductive gate. The third portion may be between the first and second portions, and may be configured to be controlled by the first conductive gate and/or by the second conductive gate.

In some embodiments, the channel region may include an impurity diffusion region along a surface thereof adjacent the single-layer insulating layer. The impurity diffusion region may be between a first portion of the channel region that is configured to be controlled by the first conductive gate and a second portion of the channel region that is configured to be controlled by the second conductive gate. The impurity diffusion region may have a same conductive type as the first and second source/drain regions. The first and second source/drain regions may extend into the substrate to a greater depth than the impurity diffusion region relative to the surface of the substrate.

In other embodiments, an impurity concentration of the impurity diffusion region may be less than that of the first and second source/drain regions. For example, the impurity concentration of the impurity diffusion region may be in a range of about 5×10¹⁴ to about 1×10¹⁵ atoms per square centimeter, and the impurity concentration of the first and second source/drain regions may be in a range of about 1×10¹⁵ to about 5×10¹⁵ atoms per square centimeter.

In some embodiments, the impurity diffusion region may further extends along a surface of the channel region from the first source/drain region to the second source/drain region. An impurity concentration of the impurity diffusion region may be in a range of about 1×10¹² to 1×10¹³ atoms per square centimeter.

In other embodiments, the first and second multi-layered charge storage structures may be first and second oxide-nitride-oxide (ONO) layers. The first and second oxide-nitride-oxide (ONO) layers may respectively include a tunnel oxide layer on the channel region, a nitride charge trapping layer on the tunnel oxide layer, and a blocking insulating layer on the nitride charge trapping layer. A thickness of the tunnel oxide layer may be about 35 to about 40 Angstroms, a thickness of the charge trapping layer may be about 70 to about 150 Angstroms, and a thickness of the blocking insulating layer may be about 100 to about 200 Angstroms.

In some embodiments, the single-layer insulating layer may be formed of a different material than the first and second multi-layered charge storage structures. For example, the single-layer insulating layer may be silicon oxide.

In other embodiments, the second memory cell of the non-volatile integrated circuit memory device may be selectively programmed by hot electron injection. More particularly, a first voltage may be applied to the first conductive gate. The first voltage may be sufficient to induce formation of an inversion layer in a portion of the channel region adjacent the first multi-layered charge storage structure. A second voltage that is greater than the first voltage may be applied to the second conductive gate. The second voltage may be sufficient to induce electron injection into the second multi-layered charge storage structure from the portion of the channel region adjacent the second multi-layered charge storage structure.

In some embodiments, the second memory cell of the non-volatile integrated circuit memory device may be selectively programmed by electron tunneling. In particular, a first voltage may be applied to the first conductive gate. The first voltage may be insufficient to induce formation of an inversion layer in a portion of the channel region adjacent the first multi-layered charge storage structure. A second voltage may be applied to the second conductive gate. The second voltage may be sufficient to induce electron tunneling into the second multi-layered charge storage structure from a portion of the channel region adjacent the second multi-layered charge storage structure.

In other embodiments, the second memory cell of the non-volatile integrated circuit memory device may be selectively erased. More particularly, a ground voltage may be applied to the first conductive gate and the first source/drain region, a negative voltage may be applied to the second conductive gate, and a positive voltage may be applied to the second source/drain region. The negative voltage and the positive voltage may be sufficient to induce electron tunneling from the second multi-layered charge storage structure into the substrate.

In some embodiments, the first memory cell of the non-volatile integrated circuit memory device may be read. In particular, a read voltage may be applied to the second conductive gate. The read voltage may be sufficient to induce formation of an inversion layer in a portion of the channel region adjacent the second multi-layered charge storage structure. A first voltage that is less than the read voltage may be applied to the first conductive gate. The first voltage may be sufficient to induce formation of an inversion layer in a portion of the channel region adjacent the first multi-layered charge storage structure when the first multi-layered charge storage structure has an erased state. However, the first voltage may be insufficient to induce formation of the inversion layer in the portion of the channel region adjacent the first multi-layered charge storage structure when the first multi-layered charge storage structure has a programmed state.

According to further embodiments of the present invention, a method of fabricating a non-volatile integrated circuit memory device may include forming a charge storage layer on a substrate, and forming a conductive layer on the charge storage layer. The conductive layer and the charge storage layer may be patterned to define a first memory cell and a second memory cell. The first memory cell may include a first conductive gate on a first multi-layered charge storage structure. The second memory cell may include a second conductive gate on a second multi-layered charge storage structure. A single-layer insulating layer may be formed on the substrate between the first and second memory cells extending along sidewalls thereof. The single-layer insulating layer may separate the first and second conductive gates by a distance of less than a thickness of the charge storage layer.

In some embodiments, patterning the conductive layer and the charge storage layer may include forming first and second dummy patterns on the conductive layer. The first and second dummy patterns may be separated by a distance greater than a thickness of the charge storage layer. Spacers may be formed on adjacent sidewalls of the first and second dummy patterns. The spacers may have a width of less than half of the distance between the first and second dummy patterns. The conductive layer and the charge storage layer may be patterned using the spacers as a mask to form the first memory cell and the second memory cell.

In other embodiments, forming the first and second dummy patterns may include. forming a dummy layer on the conductive layer, and photolithographically patterning the dummy layer to form the first and second dummy patterns. The distance between the first and second dummy gates may be greater than a minimum width that can be achieved by the photolithographically patterning, but may be less than twice the minimum width.

In some embodiments, a hard mask layer may be formed on the conductive layer prior to forming the dummy layer thereon. The first and second dummy patterns may be removed after forming the spacers on the adjacent sidewalls thereof. The hard mask layer may be patterned using the spacers as a mask to form first and second hard mask patterns separated by a distance of less than a thickness of the charge storage layer. The conductive layer and the charge storage layer may be patterned using the first and second hard mask patterns as a mask to form the first and second memory cells. As such, the first and second memory cells may be separated by a distance of less than the minimum width that can be achieved by the photolithographically patterning.

In other embodiments, forming the charge storage layer may include forming a tunnel oxide layer on the substrate, forming a nitride charge trapping layer on the tunnel oxide layer, and forming a blocking insulating layer on the nitride charge trapping layer.

In some embodiments, forming the single-layer insulating layer may include forming the single-layer insulating layer having a first portion of a first dielectric strength between the first and second conductive gates and a second portion of a second dielectric strength between the first and second multi-layered charge storage structures. The second portion of the single-layer insulating layer may have greater a dielectric strength than the first portion thereof.

In other embodiments, first and second source/drain regions may be formed in the substrate on opposite sides of the first and second charge storage layers to define a channel region therebetween. The first conductive gate may control a first portion of channel region adjacent the first multi-layered charge storage structure, and the second conductive gate may control a second portion of the channel region adjacent the second multi-layered charge storage structure. The first and/or the second conductive gate may control a third portion of the channel region between the first and second portions.

In some embodiments, impurities of a first conductive type may be implanted into the substrate between the first and second memory cells prior to forming the single-layer insulating layer. The impurities may be implanted using the first and second conductive gates as a mask to form an impurity diffusion region in the substrate therebetween.

In other embodiments, after forming the single-layer insulating layer between the first and second memory cells, impurities of the first conductive type may be implanted into the substrate on opposite sides of the first and second gates using the first and second conductive gates and the single-layer insulating layer as a mask to form first and second source/drain regions. The first and second source/drain regions may extend into the substrate to a greater depth than the impurity diffusion region relative to a surface of the substrate. An impurity concentration of the impurity diffusion region may be less than that of the first and second source/drain regions.

In some embodiments, prior to forming the charge storage layer, impurities of a first conductive type may be implanted into the substrate to form an impurity diffusion layer extending along a surface of the substrate. The charge storage layer may be formed on the impurity diffusion layer. After forming the single-layer insulating layer, impurities of the first conductive type may be implanted into the substrate on opposite sides of the first and second memory cells using the first and second conductive gates and the single-layer insulating layer as a mask to respectively form first and second source/drain regions. The first and second source/drain regions may contact the impurity diffusion layer on opposite sides thereof and may extend into the substrate beyond the impurity diffusion layer.

In other embodiments, the single-layer insulating layer may not include a charge-trapping layer. Also, the single-layer insulating layer may be formed of a different material than the first and second multi-layered charge storage structures. For example, the single-layer insulating layer may be formed of silicon oxide.

According to still further embodiments of the present invention, a depletion-mode non-volatile integrated circuit memory device may include a substrate including first and second source/drain regions therein and a channel region therebetween. An impurity diffusion region may extend along a surface of the channel region from the first source/drain region to the second source/drain region. The device may further include a first memory cell on the channel region adjacent the first source/drain region and a second memory cell on the channel region adjacent the second source/drain region. The first memory cell may include a first conductive gate on the impurity diffusion region and a first charge storage structure therebetween, and the second memory cell may include a second conductive gate on the impurity diffusion region and a second charge storage structure therebetween. An insulating layer may extend on the channel region between the first and second memory cells along sidewalls thereof. The insulating layer may separate the first and second conductive gate by a distance of less than a thickness of the first charge storage structures.

Some other embodiments of the present invention provide a non-volatile memory device. The non-volatile memory device may include two memory cells formed on a channel region between two junction regions in a substrate. The two memory cells may be spaced apart from each other. The two memory cells may be symmetric to and may be electrically insulated from each other by means of a separate insulation layer. Each of the memory cells may include a memory layer and a gate. Channel regions may be defined in the substrate under the two memory cells and between two junction regions.

In some embodiments, the memory layer may include a tunnel oxide layer, a charge-trapping layer and a blocking insulating layer stacked in sequence. For instance, the memory layer may be an ONO layer configured with a thermal oxide layer as the tunnel oxide layer, a nitride layer as the charge-trapping layer, and an oxide layer as the blocking insulating layer. The tunnel oxide layer may have a thickness in a range of about 35 Å to about 40 Å. The blocking insulating layer may have a thickness in a range of about 100 Å to about 200 Å. The charge-trapping layer may have a thickness in a range of about 70 Å to about 150 Å.

In other embodiments, by applying an appropriate voltage to the substrate, the gate of each memory cell, and the two junction regions, respectively, charges may be injected from the channel to the charge-trapping layer or vice versa through the tunnel oxide layer. That is, the charges may be injected from the channel to the charge-trapping layer or vice versa through the tunnel oxide layer by tunneling or jumping over a potential barrier of the tunnel oxide layer. The charges may be any one of electrons, hot electrons, hot holes and holes, which may depend on a voltage applied to the substrate, the gate, and/or the junction regions.

In some embodiments, the charge-trapping layer may use other materials capable of storing charges as well as the nitride layer. That is, the charge-trapping layer may employ an insulator with a relatively high charge trap density, such as an aluminum oxide layer (Al₂O₃), a hafnium oxide layer (HfO), a hafnium-aluminum oxide layer (HfAlO), a hafnium silicon oxide layer (HfSiO), or the like. In addition, doped polysilicon, metal, or nanocrystals thereof may be used as the charge-trapping layer.

In other embodiments, the blocking insulating layer may employ an insulator with a relatively high charge trap density, such as an aluminum oxide layer (Al₂O₃), a hafnium oxide layer (HfO), a hafnium-aluminum oxide layer (HfAlO), a hafnium silicon oxide layer (HfSiO), or the like, as well as the oxide layer.

In some embodiments, the separate non-charge trapping insulating layer may be an insulating layer, e.g., a silicon oxide layer, which cannot store charges therein. Alternatively, the insulating layer may store a relatively small amount of charges that may not have an effect on the threshold voltage of the device, unlike the charge-trapping layer. The separate insulating layer may be an arbitrary insulating layer that does not include a charge-trapping region. In addition, the separate insulating layer may be a single layer insulating layer.

According to some embodiments of the present invention, since the two memory cells are physically separated from each other by the separate insulating layer, the separate insulating layer may have a width that is as narrow as possible, for higher device integration. In particular, the width of the separate insulating layer may be less than the thickness of the memory layer.

In some embodiments, in a read operation, the voltage applied to each memory cell may be capacitively coupled to a channel region under the separate insulating layer, to thereby control the portion of the channel region under the insulating layer.

In other embodiments, in order to control the portion of the channel region under the separate insulating layer, the memory device may further include an impurity diffusion region in the channel region under the separate insulating layer. The impurity diffusion region may be doped with impurity ions which are identical in conductive type to the two junction regions. That is, the impurity diffusion region may be disposed between the channel regions under the two memory cells. The impurity diffusion region may be formed shallower than the junction regions. Furthermore, the impurity concentration of the impurity diffusion region may be lower than those of the junction regions.

In some embodiments, the memory device may further include an impurity diffusion layer in the channel region under the memory cells. The impurity diffusion layer may lower the threshold voltages of the memory cells. Thus, it may be possible to more easily control the channel region under the separate insulating layer.

In other embodiments, a ground voltage may be applied to one junction region and the semiconductor substrate, a control voltage may be applied to the other junction region, a first high voltage may be applied to the gate of the memory cell adjacent to the junction region to which the control voltage is applied, and a second high voltage lower than the first high voltage may be applied to the gate of the memory cell adjacent to the junction region to which the ground voltage is applied. As such, hot electrons may be injected from the channel region of the semiconductor substrate into the charge-trapping layer of the memory layer of the memory cell to which the first high voltage is applied, by hot electron injection.

In some embodiments, the second high voltage may enable a channel to be formed under the memory cell adjacent to the junction region to which the ground voltage is applied. That is, application of the second high voltage may form the channel through which the current flows. The first high voltage may enable the hot electrons to be generated around the junction region to which the control voltage is applied, and may cause the generated hot electron to be injected into the charge-trapping layer of the memory layer. The control voltage may be used for generating a horizontal electric field between one junction region and the other junction region. The control voltage, for example, may be in a range of about 3.5 V to about 5.5 V. For instance, the first high voltage may range from about 4.5 V to about 6.5 V, and the second high voltage may range from about 3 V to about 4.5 V.

In other embodiments, the ground voltage may be applied to the two junction regions and the semiconductor substrate, a programming/erasing voltage may be applied to the gate of one memory cell, and the ground voltage or a programming/erasing prevention voltage which is lower than the programming/erasing voltage may be applied to the gate of the other memory cell. As such, electrons may be injected or emitted by a tunneling effect from the channel region of the semiconductor substrate into the charge-trapping layer of the memory cell to which the programming/erasing voltage is applied or vice versa. For example, if the tunnel oxide layer has a thickness of 30 Å or less, direct tunneling may occur. On the other hand, if the tunnel oxide has a thickness of 30 Å or greater, Fowler-Nordheim tunneling may occur.

In some embodiments, if the programming/erasing voltage and the programming/erasing prevention voltage are all of positive polarity, electrons may be injected from the semiconductor substrate into the charge-trapping layer of the memory cell to which the programming/erasing voltage is applied, through the tunnel oxide layer. At this time, the holes may move in opposite direction to the electrons. On the contrary, if the programming/erasing voltage and the programming/erasing prevention voltage are all of negative polarity, electrons may be injected from the charge-trapping layer of the memory cell to which the programming/erasing voltage is applied into the semiconductor substrate, through the tunnel oxide layer. At this time, the holes move in opposite direction to the electrons.

In other embodiments, the programming/erasing voltage may be adjusted such that the electrons in the channel region can penetrate through the tunnel oxide layer. For instance, the programming/erasing voltage may be about 15 V. The programming/erasing prevention voltage may be applied to prevent the memory cell from being programmed/erased, so that its voltage level may be lower than the programming/erasing voltage level. For instance, the programming/erasing prevention voltage may be the ground voltage or a relatively low voltage in a range of about 0.4 V to about 0.5 V. If the programming/erasing voltage is applied to both of the two memory cells, the charges may simultaneously move in the two memory cells.

In some embodiments, the ground voltage may be applied to one junction region and the semiconductor substrate, a first high voltage of a positive polarity may be applied to the other junction region, a second high voltage of a negative polarity may be applied to the gate of the memory cell adjacent to the junction region to which the first high voltage is applied, and the ground voltage may be applied to the gate of the memory cell adjacent to the junction region to which the ground voltage is applied. As such, hot holes, which may be generated by a band-to-band tunneling effect in the junction region to which the first high voltage is applied, may be injected into the charge-trapping layer of the memory cell to which the second high voltage is applied. The hot holes may be generated in the junction region overlapping the gate. Portions of the hot holes may be injected into the charge-trapping layer due to the electric field caused by the second high voltage of negative polarity applied to the gate. For instance, the first high voltage may range from about 3.5 V to about 5.5 V, and the second high voltage may range from about −3 V to about −1 V. The second high voltage may be applied to the gates of the two memory cells, and the first high voltage may be applied to the two junction regions. As such, hot holes may be generated in both of the two junction regions, and may be injected into the charge-trapping layers of the two memory cells.

In other embodiments, if electrons are stored in the charge-trapping layer, e.g., the memory cell is in a programmed state or an ‘OFF’ state, the threshold voltage of the memory cell may be increased. On the contrary, if the electrons are emitted from the charge-trapping layer, e.g., the memory cell is in an erased state or an ‘ON’ state, the threshold voltage may be decreased. For example, it is possible to set the threshold voltage of the memory cell in the programmed state to be about 3 V, and the threshold voltage in the erased state to be about −3 V.

In some embodiments, to perform a read operation on the memory cell in the programmed state or the erased state, a ground voltage (i.e., 0V) may be applied to one junction region; a read voltage Vread which is higher than the ground voltage may be applied to the other junction region; a first control voltage may be applied to the gate of the memory cell adjacent to the junction region to which the ground voltage is applied (wherein the first control voltage may be higher than the ‘ON’ state threshold voltage and may be lower the ‘OFF’ state threshold voltage); a second control voltage may be applied to the gate of the memory cell adjacent to the junction region to which the read voltage is applied (wherein the second control voltage may be higher than the ‘OFF’ state threshold voltage); and the ground voltage or a positive low voltage which may be higher than the ground voltage may be applied to the semiconductor substrate.

In other embodiments, the read voltage, for example, may be in a range of about 0.5 V to about 1.5 V. The first and second control voltages may be independent from each other, and may be the ground voltage, or may be a in range from about 2 V to about 6 V. The positive low voltage applied to the substrate, for example, may range from about 0.4 V to about 0.5 V. When applying the positive low voltage to the substrate, the width of a depletion region between the junction regions and the substrate may be decreased, which may improve short channel effects in the read operation.

In some embodiments, the two memory cells may be in the programmed state, i e., the ‘OFF’ state. Accordingly, the threshold voltages of the two memory cells may be about 3 V. At this time, in order to perform the read operation on a left memory cell, i.e., first memory cell, a ground voltage may be applied to a first junction region adjacent to the first memory cell and to the substrate; a voltage in a range of about 0.5 V to about 1.5 V may be applied to a second junction region adjacent to a right memory cell, i.e., second memory cell; and a ground voltage as a first control voltage may be applied to the gate of the first memory cell, and a second control voltage in a range of about 2 V to about 6 V may be applied to the gate of the second memory cell to generate a channel. Under these bias conditions, a channel may be formed under the second memory cell (i e., the second memory cell may be turned on), whereas a channel may not be formed under the first memory cell (i.e., the first memory cell may be turned off). In other words, the first memory cell may have a high resistance state, such that current hardly flows between the first and second junction regions.

In contrast, in other embodiments, when the first memory cell is in the ‘ON’ state, the threshold voltage may be about −3 V. Thus, the channel may be formed under the first memory cell as well as under the second memory cell. As a result, the first and second memory cells may have a low resistance state, such that the current flows between the junction regions.

In some embodiments, during a read operation, the control voltage of about 2 V to about 6 V applied to the gate may be capacitively coupled to the channel region under the separate insulating layer, so that the channel region is in the ‘ON’ state. However, when the impurity diffusion region is formed under the separate insulating layer, it may be unnecessary to couple the control voltage to the portion of the channel region under the separate insulating layer. In addition, where the impurity diffusion layer has already been formed between the junction regions, it may be possible to obtain a similar effect.

Some embodiments of the present invention may provide a method of fabricating a memory device. The method for fabricating the memory device may include: forming a memory layer having a tunnel oxide layer, a charge-trapping layer and a blocking insulating layer stacked on a substrate in sequence; forming a conductive layer on the memory layer; forming a first memory cell and a second memory cell by patterning the conductive layer and the memory layer, wherein the first and second memory cells may be spaced apart from each other; forming insulating spacers on sidewalls of each memory cell, wherein the insulating spacers between the memory cells may be connected to each other to form a separate non-charge trapping insulating layer; and forming a first junction region on lateral side of the first memory cell and a second junction region on a lateral side of the second memory cell by performing an ion implantation process.

In some embodiments, before forming the insulating spacer and the separate insulating layer, the method for forming the memory device may further include forming a third junction region in the semiconductor substrate between the memory cells by implanting impurity ions of a same conductive type as the first and second junction regions. The third junction region may be formed shallower than the first and second junction regions. The third junction region may be lower in doping concentration than the first and second junction regions.

In other embodiments, before the forming of memory layer, the method for forming the memory device may further include forming an impurity diffusion layer on a surface of the semiconductor substrate by implanting impurity ions of an opposite conductive type than the semiconductor substrate. The memory layer may be formed by stacking an oxide layer, a nitride layer, and an oxide layer on the substrate in sequence.

In other embodiments, the forming of the first and second memory cells may further include: forming a first dummy pattern and a second dummy pattern on the conductive layer; forming spacers on sidewalls of the dummy patterns; removing the dummy patterns; etching the exposed conductive layer and the memory layer using the spacers as an etch mask; and removing the spacers. The method may further include forming a hard mask layer on the conductive layer before forming the dummy patterns. The hard mask layer may be etched to form hard mask layer patterns after removing the dummy patterns, and the exposed conductive layer and the memory layer may be etched using the hard mask layer patterns as an etch mask.

### BRIEF DESCRIPTION OF THE DRAWINGS

FIG. 1A is a cross-sectional view of a first conventional non-volatile memory device, and FIG. 1B is an equivalent circuit diagram illustrating the first conventional non-volatile memory device of FIG. 1A;

FIG. 2A is a cross-sectional view of a second conventional non-volatile memory device, and FIG. 2B is an equivalent circuit diagram illustrating the second conventional non-volatile memory device of FIG. 2A;

FIG. 3A is a cross-sectional view of a third conventional non-volatile memory device, and FIG. 3B is an equivalent circuit diagram illustrating the third conventional non-volatile memory device of FIG. 1A;

FIG. 4A is a cross-sectional view of a fourth conventional non-volatile memory device, and FIG. 4B is an equivalent circuit diagram illustrating the fourth conventional non-volatile memory device of FIG. 4A;

FIG. 5A is a cross-sectional view of a non-volatile memory device according to some embodiments of the present invention, and FIG. 5B is an equivalent circuit diagram illustrating the non-volatile memory device of FIG. 5B;

FIG. 6A is a cross-sectional view of a non-volatile memory device according to other embodiments of the present invention, and FIG. 6B is an equivalent circuit diagram illustrating the non-volatile memory device of FIG. 6B;

FIG. 7A is a cross-sectional view of a non-volatile memory device according to further embodiments of the present invention, and FIG. 7B is an equivalent circuit diagram illustrating the non-volatile memory device of FIG. 7B;

FIGS. 8 to 10 are cross-sectional views illustrating methods for injecting electrons into a charge-trapping layer of a non-volatile memory device according to some embodiments of the present invention;

FIGS. 11 to 13 are cross-sectional views illustrating methods for injecting holes into a charge-trapping layer of a non-volatile memory device according to some embodiments of the present invention;

FIGS. 14 and 15 are cross-sectional views illustrating a read operation for the non-volatile memory device of FIG. 5A according to some embodiments of the present invention;

FIGS. 16 and 17 are cross-sectional views illustrating a read operation for the non-volatile memory device of FIG. 6A according to other embodiments of the present invention;

FIGS. 18 and 19 are cross-sectional views illustrating a-read operation for the non-volatile memory device of FIG. 7A according to further embodiments of the present invention;

FIGS. 20 to 26 are cross-sectional views illustrating methods for fabricating the non-volatile memory device of FIG. 5A according to some embodiments of the present invention; and

FIGS. 27 and 28 are cross-sectional views illustrating methods for fabricating the non-volatile memory device of FIG. 7A according to further embodiments of the present invention.

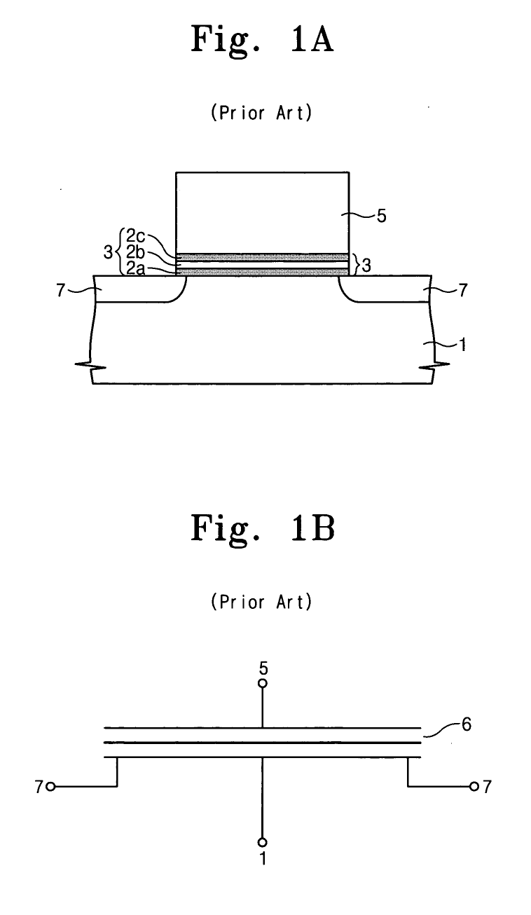

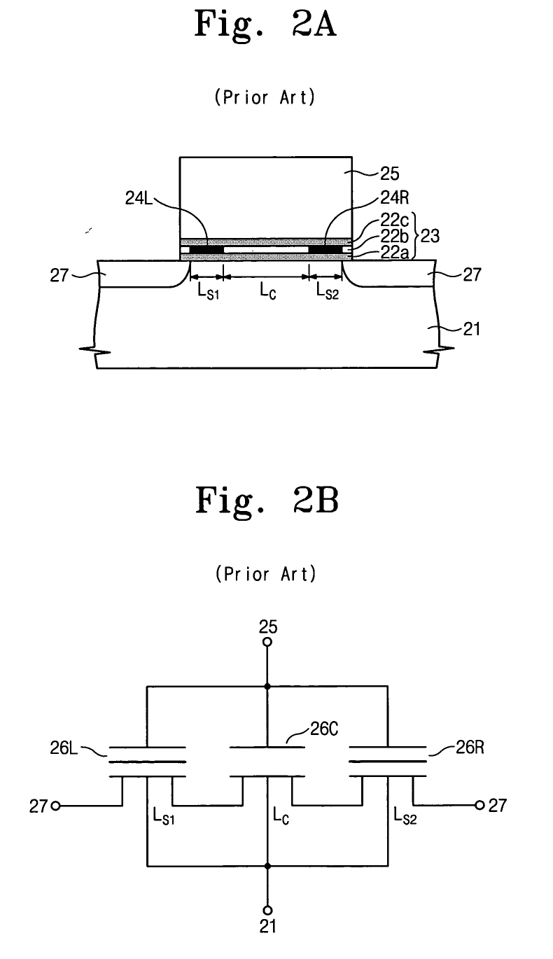

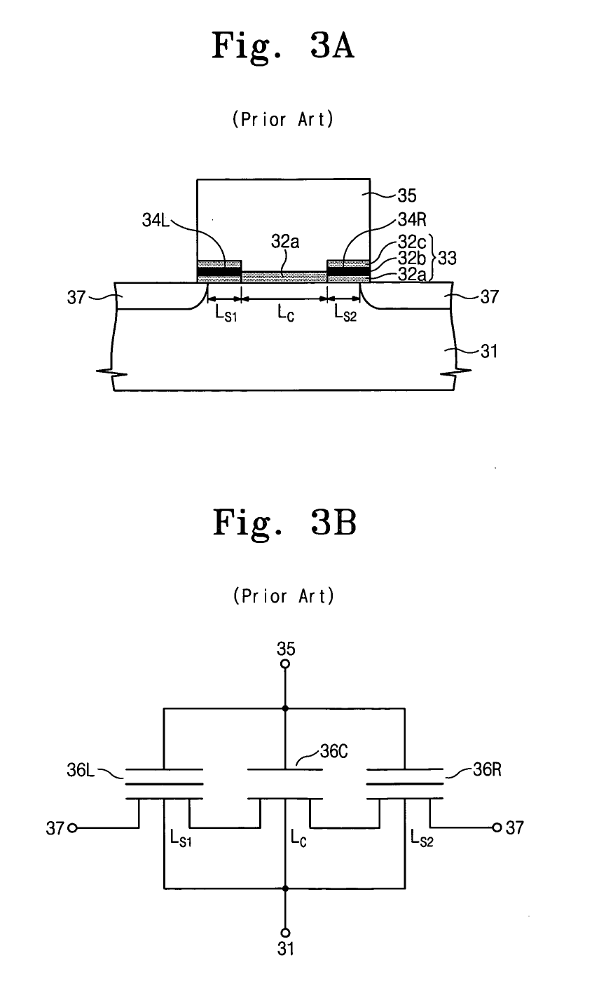

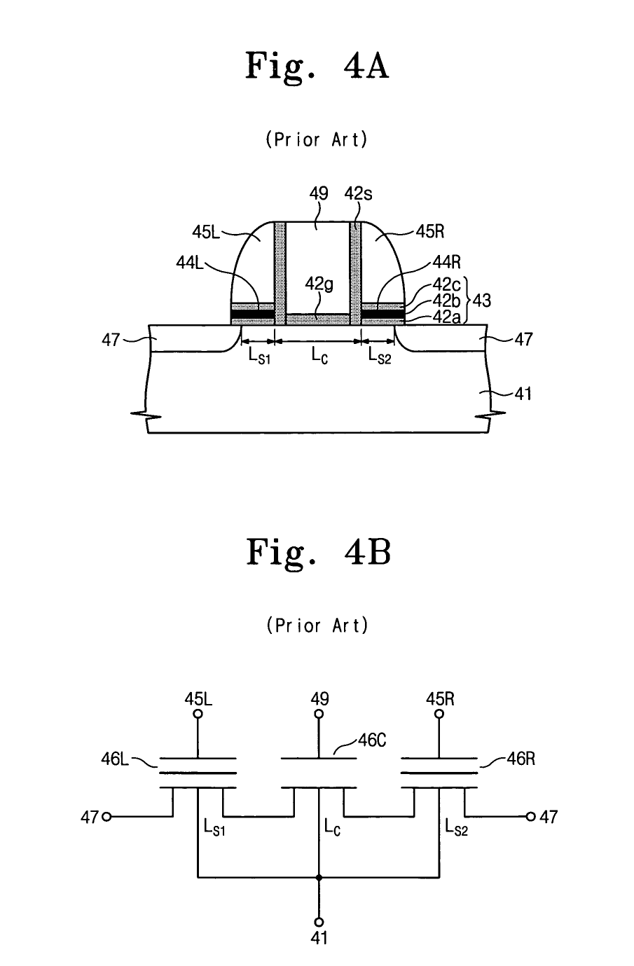

### DETAILED DESCRIPTION OF EMBODIMENTS OF THE INVENTION

The present invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein.

Exemplary embodiments of the present invention are directed to a multi-bit non-volatile memory device, a method for operating the same, and a method for fabricating the same. The memory device, according to some embodiments of the present invention, includes two memory cells between two junction regions of a semiconductor substrate. The two memory cells are physically separated by a thin separate insulating layer, which does not include a charge-trapping region.

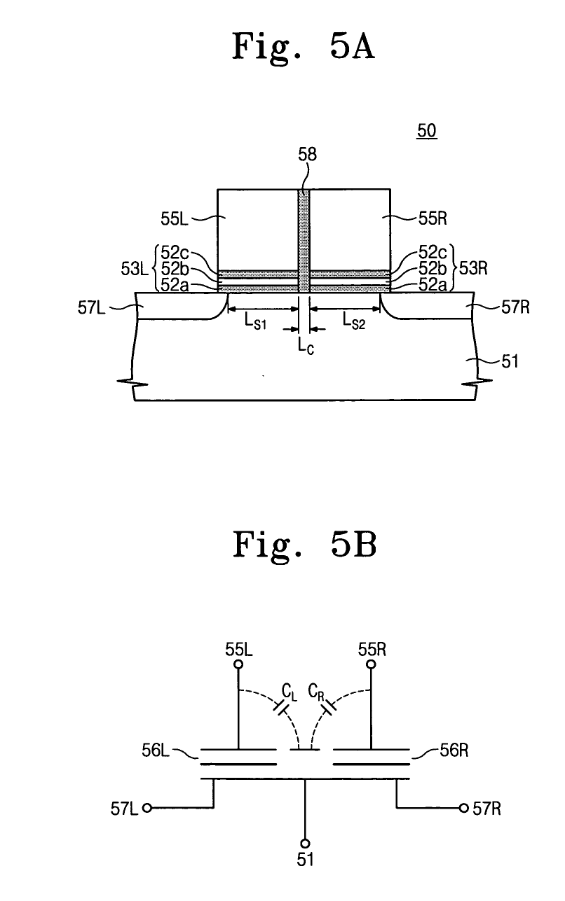

FIG. 5A is a cross-sectional view of a non-volatile memory device according to some embodiments of the present invention, and FIG. 5B is-an equivalent circuit diagram illustrating the non-volatile memory device of FIG. 5A. Referring to FIGS. 5A and 5B, the non-volatile memory device includes a substrate 51, two junction regions 57L and 57R which are spaced apart from each other, and two memory cells 56L and 56R formed over channel regions Ls1 and Ls2 between the two junction regions 57L and 57R. The two memory cells 56L and 56R are separated from each other by means of a separate insulating layer 58. Under the separating insulating layer 58, channel region Lc is defined.

A first memory cell 56L, i.e., the left memory cell in FIGS. 5A and 5B, includes a first memory layer 53L and a first gate 55L stacked on the substrate 51. Likewise, a second memory cell 56R, i.e., the right memory cell in FIGS. 5A and 5B, includes a second memory layer 53R and a second gate 55R stacked on the substrate 51. Under the first memory cell 56L, a first channel region Ls1 is provided. Similarly, a second channel region Ls2 is provided under the second memory cell 56R. Meanwhile, a third channel region Lc is provided under the separate insulating layer 58. The first channel region Ls1 is controlled by the first gate 55L of the first memory cell 56L, and the second channel region Ls2 is controlled by the second gate 55R of the second memory cell 56R. Meanwhile, the third channel region Lc is controlled by the first gate 55L and/or the second gate 55R. In other words, the third channel region Lc is controlled by coupling capacitance C_{L} and C_{R}, which can be formed by a fringe electrical field effect caused by the first and second gates 55L and 55R disposed on both sides of the separate insulating layer 58.

Based on the conductive types of the substrate 51 and the junction regions 57L and 57R, the memory cells 56L and 56R may be n-channel devices or p-channel devices. For instance, if the substrate 51 is p-type and the junction regions 57L and 57R are n-type, the memory cells are n-channel memory cells. Vice versa, if the substrate 51 is n-type and the junction regions 57L and 57R are p-type, the memory cells are p-channel memory cells.

According to some embodiments of the present invention, the two memory cells 56L and 56R may be symmetrical to each other. For example, in the first memory cell 56L, the left junction region 57L may act as a source, and the right junction region 57R may act as a drain. On the contrary, in the second memory cell 56R, the left junction region 57L may act as a drain, and the right junction region 57R may act as a source. The junction regions 57L and 57R, in case of an n-channel memory cell, may be formed by implanting arsenic (As) or the like at a predetermined energy level in a range of about 30 keV to about 50 keV with a dose of about 1×10¹⁵ to about 5×10¹⁵ atoms/cm². For the p-channel memory cell, the junction regions 57L and 57R may be formed by implanting boron (B) or the like at a predetermined energy level in a range of about 30 keV to about 50 keV with a dose of about 1×10¹⁵ to about 5×10¹⁵ atoms/cm².

Each of the first and second memory layers 53L and 53R includes a tunnel oxide layer 52a, a charge-trapping layer 52b and a blocking insulating layer 52c, which are stacked on the substrate 51. The charge-trapping layer 52b may be a nitride layer. Also, the charge-trapping layer 52b may-employ an insulator with a relatively high charge trap density, such as an aluminum oxide layer (Al₂O₃), a hafnium oxide layer (HfO), a hafnium-aluminum oxide layer (HfAlO), a hafnium silicon oxide layer (HfSiO), or the like. In addition, doped polysilicon, metal, or nanocrystals thereof may be used as the charge-trapping layer 52b.

The blocking insulating layer 52c may be an oxide layer. In addition, the blocking insulating layer 52c may employ an insulator with a relatively high dielectric constant, such as an aluminum oxide layer (Al₂O₃), a hafnium oxide layer (HfO), a hafnium-aluminum oxide layer (HfAlO), a hafnium silicon oxide layer (HfSiO), or the like, as well as the oxide layer.

The thickness of the tunnel oxide layer 52a is selected to allow charges to penetrate therethrough during a predetermined memory operation, whereas the thickness of the blocking layer 52c is selected such that the charges cannot penetrate therethrough. For instance, the tunnel oxide layer 52a may be a thermal oxide layer having a thickness, for example, of about 35 Å to about 40 Å, and the blocking insulating layer 52c may be an oxide layer having a thickness, for example, of about 100 Å to about 200 Å. The charge-trapping layer 52b may be a nitride layer having a thickness, for example, of about 70 Å to about 150 Å.

When applying a bias voltage to the substrate 51, the junction regions 57L and 57R, and the gates 55L and 55R, charges may penetrate through the tunnel oxide layer 52a via a tunneling effect and/or may “jump” over a potential barrier of the tunnel oxide layer 52a, so that the charges may be trapped in and/or emitted from the charge-trapping layer 52b. Because the charge-trapping layer 52b has relatively low conductivity, the charges trapped in the charge-trapping layer 52b may not move or diffuse therefrom. The blocking insulating layer 52c electrically isolates the charge-trapping layer 52b from the gate 55L and 55R, so as to prevent the charges from moving therebetween. The thicknesses of the tunneling oxide layer 52a, the charge-trapping layer 52b, and the blocking insulating layer 52c may be appropriately selected according to a desired bias condition and/or programming/erasing mode characteristics.

When injecting charges, e.g., electrons, into the charge-trapping layer of the memory cell, it may be undesirable for charges to accumulate at the separate insulating layer 58 between the two memory cells 56L and 56R. Thus, a predetermined insulating layer that does not include a charge-trapping region therein is used as the separate insulating layer 58 in embodiments of the present invention. For example, if charges were accumulated at the separate insulating layer 58 during a programming operation, program efficiency may be deteriorated. In addition, a threshold voltage of the memory cell for a read operation may be affected. Also, in order to completely remove the charges accumulated in the separate insulating layer 58, an erasing time for an erasing operation may be increased. In consideration of the above, a silicon oxide layer may be used as the separate insulating layer 58. The separate insulating layer 58 may be formed of a single-layer.

In addition, to allow for higher degrees of device integration, the separate insulating layer may be formed as thin as possible. More particularly, the width of the separate insulating layer 58 is less than the thickness of the memory layer 53L and 53R. Also, in order to enhance controllability of the gate with respect to the third channel region Lc, portions of the separate insulating layer between the memory layers 53L and 53R may have a relatively high dielectric constant, whereas portions of the separate insulating layer between the gates 55L and 55R may have a relatively low dielectric constant to reduce a coupling capacitance therebetween. The gates 55L and 55R may be formed of polysilicon doped with impurities.

The memory device of FIG. 5A may be employed in a relatively large memory array. As stated above, since the memory device of the present invention includes two memory cells separated by a distance of less than a thickness of the charge storage memory layers by the thin separate insulating layer, it may be possible to package more memory cells in a given area. For instance, a memory device according to some embodiments of the present invention may be implemented in a memory array for a NAND flash memory, a NOR flash memory, or the like.

FIG. 6A is a cross-sectional view of a non-volatile memory device according to other embodiments of the present invention, and FIG. 6B is an equivalent circuit diagram illustrating the non-volatile memory device of FIG. 6A. The non-volatile memory device of this embodiment further includes an impurity diffusion layer 68 in the channel regions Ls1, Lc and Ls2. The impurity diffusion layer 68 is identical in conductive type to the junction regions 57L and 57R. Therefore, by controlling the doping concentration of the impurity diffusion layer 68 appropriately, each of memory cells 56L and 56R may be a depletion type memory cell having its threshold voltage as a negative value (for an n-channel memory cell). In this case, in contrast to the memory cell of FIGS. 5A and 5B, it may be unnecessary and/or relatively easy to control the third channel region Lc by the gate, due to the presence of the impurity diffusion layer 68. In addition, since the impurity diffusion layer 68 is also formed in the first and second channel regions Ls1 and Ls2 under the first and second memory cells 56L and 56R, it may be possible to control the channel using a relatively low voltage.

The impurity diffusion layer 68 may be formed by implanting p-type or n-type impurity ions. In case of a p-type device, the impurity diffusion layer 68 may be formed by implanting boron ions at a predetermined energy level in a range of about 30 keV to about 50 keV with a dose of about 1×10¹² to about 1×10¹³ atoms/cm². In case of an n-channel device, arsenic ions or phosphor ions may be implanted at a predetermined energy level in a range of about 30 keV to about 50 keV with a dose of about 1×10 ¹² to about 1×10¹³ atoms/cm² to form the impurity diffusion layer 68.

For example, the dose of the ion implantation for the impurity diffusion layer 68 may be determined such that the impurity ions which are opposite in conductive type to the substrate 51 are implanted and accumulated in the channel regions, or the conductive types of the channel regions are converted. According to the concentration of the impurity diffusion layer 68, a channel may be formed under the memory cell by generating horizontal electric field between two junction regions. The dose of the ion implantation may be selected such that an inversion layer channel may not be formed under a memory cell into which charges have been implanted (i.e., a programmed cell) without applying the horizontal electric field between the two junction regions, but such that an inversion layer channel may be formed under a memory cell into which charges have not been implanted (i.e., an erased cell).

The threshold voltage of each memory cell may also be controlled based on the work function of the gate. For instance, where the gate is formed of polysilicon doped with impurities, the work function of the gate may be controlled by appropriately adjusting the concentration of the impurities. In addition, the work function of the gate may be controlled by forming a multi-layer gate including polysilicon and metal.

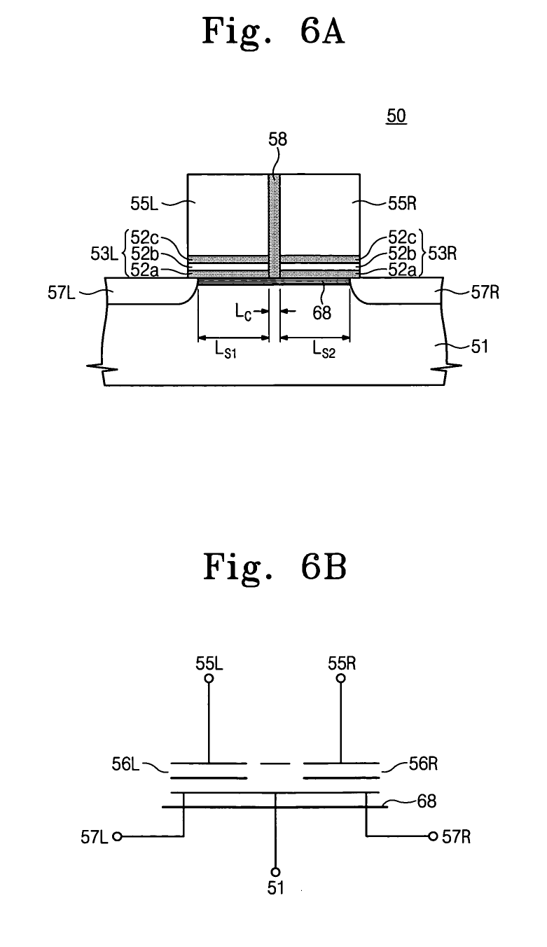

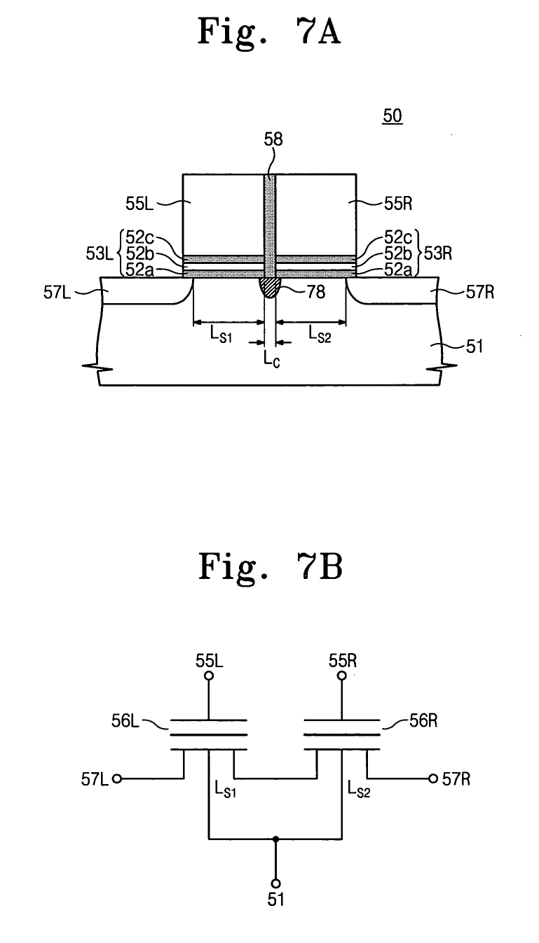

FIG. 7A is a cross-sectional view of a non-volatile memory device according to further embodiments of the present invention, and FIG. 7B is an equivalent circuit diagram illustrating the non-volatile memory device of FIG. 7A. In comparison with the non-volatile memory device of FIGS. 5A and 5B, the non-volatile memory device of FIG. 7A further includes an impurity diffusion region 78 at the third channel region under the separate insulating layer 58. The impurity diffusion region 78 is formed by implanting impurity ions which are identical in conductive type to the junction regions 57L and 57R. Therefore, similar to the non-volatile memory device described above with reference to FIGS. 6A and 6B, the third channel region Lc may be controlled by the gates 55L and 55R of each memory cell. However, due to the presence of the impurity diffusion region 78, it may be unnecessary to control the third channel region using the gates 55L and 55R.

The impurity diffusion region 78 may be formed shallower than the junction regions 57L and 57R. Furthermore, the impurity concentration of the impurity diffusion region 78 may be lower than those of the junction regions 57L and 57R. For example, in case of an n-type device, the impurity diffusion layer 78 may be formed by implanting arsenic ions at a predetermined energy level in a range of about 10 keV to about 30 keV with a dose of about 5×10¹⁴ to about 1×10¹⁵ atoms/cm². In case of a p-channel device, boron ions may be implanted under similar conditions.

Programming/erasing operations for the memory device illustrated in FIGS. 5A and 5B will be illustrated with reference to FIGS. 8 to 13. Programming/erasing operations for the memory devices of FIGS. 6A and 6B and of FIGS. 7A and 7B may be similar to that of the memory device of FIGS. 5A and 5B. In the following examples, the programming/erasing operations will be set forth assuming that the memory cell is an n-channel memory device.

A programming operation for memory devices according to some embodiments of the present invention may inject electrons into the charge-trapping layer of the memory cell. Likewise, an erasing operation may emit electrons from the charge-trapping region to the channel region. If the charge is a hole, the above directions may be reversed. In addition, the programming operation may increase the threshold voltage of the memory cell, whereas the erasing operation may decrease the threshold voltage of the memory cell. Also, the programmed memory cell state may be referred to as an ‘OFF’ state, and the erased memory cell state may be referred to as an ‘ON’ state. For convenience, in the following examples, the threshold voltage of the programmed memory cell (i.e., the memory cell in the ‘OFF’ state) may be about 3 V, and the threshold voltage of the erased memory cell (i.e., the memory cell in the ‘ON’ state) may be about −3V.

According to some embodiments of the present invention as described above, since the memory cells 56L and 56R are physically insulated from each other by the separate insulating layer 58 therebetween, each memory cell may be independently programmed/erased. That is, one of the two memory cells may be selectively programmed/erased, or both of the memory cells may be programmed/erased. Alternatively, neither of the two memory cells may be programmed/erased.

FIGS. 8 to 10 are cross-sectional views illustrating a method for injecting electrons into the charge-trapping layer 52b of the memory layer 53L and 53R (i.e., programming), and FIGS. 11 to 13 are cross-sectional views illustrating a method of injecting holes into the charge-trapping layer 52b of the memory layer 53L and 53R (i.e., erasing). For convenience and clarity, a charge-injected region in the charge-trapping layer 52b is represented as a shaded portion. In the drawings, the conductive state of the channel region, i.e., the state that the inversion layer is formed, is represented as a hatched line. Herein, the left charge-trapping layer is denoted by reference numeral 52bl, and the right charge-trapping layer is denoted by reference numeral 52br.

FIG. 8 is a cross-sectional view illustrating a method for injecting hot electrons into the charge-trapping layers 52bl and 52br. More particularly, FIG. 8 illustrates a method for injecting electrons into the charge-trapping layer 52br of the second memory cell 56R. In order to selectively inject electrons into the charge-trapping layer 52br of the second memory cell 56R, a control voltage in a range of about 3.5 V to about 5.5 V is applied to the right junction region 57R, i.e., the drain, and a ground voltage of about 0 V is applied to the left junction region 57L, i.e., the source, as well to as the substrate 51. To the gate 55L of the first memory cell 56L, a voltage in a range of about 3 V to about 5 V is applied to form the inversion layer channel 89a. The voltage applied to the gate 55R of the second memory cell 56R is higher than the voltage applied to the gate 55L of the first memory cell 56L. For example, the voltage applied to the gate 55R of the second memory cell 56R may be in a range of about 4.5 V to about 6 V. Accordingly, the channel 89c is pinched-off at the substrate under the second memory cell 56R, and the hot electrons “jump” over the potential barrier of the second tunnel oxide layer 52a to be injected into the charge-trapping layer 52br. Therefore, the second memory cell 56R is programmed. The second memory cell 56R in the programmed state has a threshold voltage of about 3V.

The channel 89b under the separate insulating layer 58 may be formed by a fringe electric field (ε_{y}), due to the voltage applied to the first and second gates 55L and 55R.

For the channel 89a generated under the first gate 55L, the voltage applied to the first gate 55L should be sufficient to generate the inversion layer at the surface of the substrate regardless of whether the first memory cell is in the programmed or the erased state. In other words, even if electrons have been injected into the charge-trapping layer 52bl and thereby increased the threshold voltage, e.g., to about 3 V, the voltage applied to the first gate 55L should be sufficient to induce formation of the channel 89a . For example, if the threshold voltage is 3V at the state that the electrons are injected, i.e., ‘OFF’/programmed state, the voltage applied to the first gate 55L should be greater than 3V, for example, about 4V or higher.

In addition, in this manner, it may be possible to selectively inject electrons into the charge-trapping layer 52bl of the first memory cell by interchanging the voltages for the first gate 55L and the left junction region 57L with the voltages for the second gate 55R and the right junction region 57R described above.

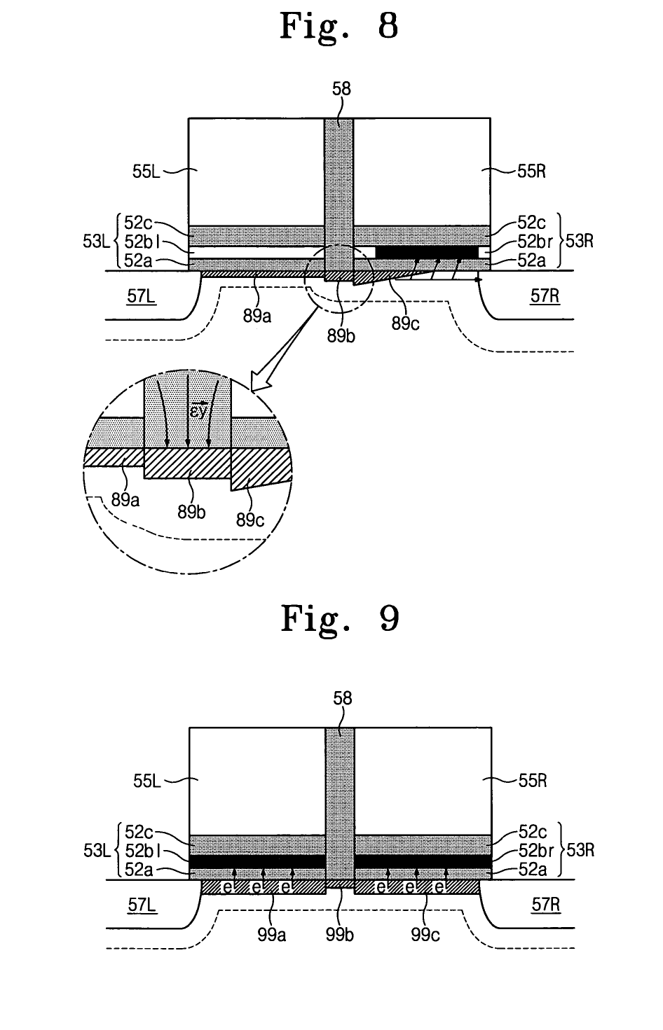

FIG. 9 illustrates that electrons are injected into both the first and second charge-trapping layers 52bl and 52br via a tunneling effect. For example, where the tunnel oxide layer 52a of the first and second memory layers 53L and 53R has a thickness of about 30 Å or less, direct tunneling may occur. On the other hand, if the thickness of the tunnel oxide 52a is about 30 Å or more, Fowler-Nordheim tunneling may occur.

Still referring to FIG. 9, a relatively high voltage in a range of about 10 V to about 20 V (for example, about 15V) is applied to both the first and second gates 55L and 55R, so that electrons in the channels 99a and 99c are injected into the charge-trapping layers 52bl and 52br through the tunnel oxide layer 52a. Meanwhile, a ground voltage, i.e., 0 V, is applied to the junction regions 57L and 57R and to the substrate 51. As a result, the electrons in the channel 99a and 99c may penetrate through the tunnel oxide layer 52a, and may be injected into the first and second charge-trapping layers 52bl and 52br so that the two memory cells 56R and 56L are both programmed in the same operation. The memory cells in the programmed state, for example, may have a threshold voltage of about 3 V.

Also, by changing the polarity of the voltage applied to the first and second gates 55L and 55R, e.g., if a voltage in a range of about −20 V to about −10 V (for example, about −15 V) is applied to both the first and second gates 55L and 55R, the holes in the channel 99a and 99c may be injected into the charge-trapping layers 52bl and 52br through the tunnel oxide layer 52a. In other words, electrons already injected into the charge-trapping layers 52bl and 52br may be emitted from the charge-trapping layers 52bl and 52br to the substrate through the tunnel oxide layer 52a. Hole injection or electron emission may dominantly occur based on selection of predetermined thicknesses of the memory layers 53L and 53R and/or predetermined materials. When holes are injected into the charge-trapping layer 52bl and 52br (i.e., when injected electrons are emitted from the charge-trapping trapping layer 52bl and 52br), the memory device is erased. The memory cells in the erased state may have a threshold voltage of about −3 V.

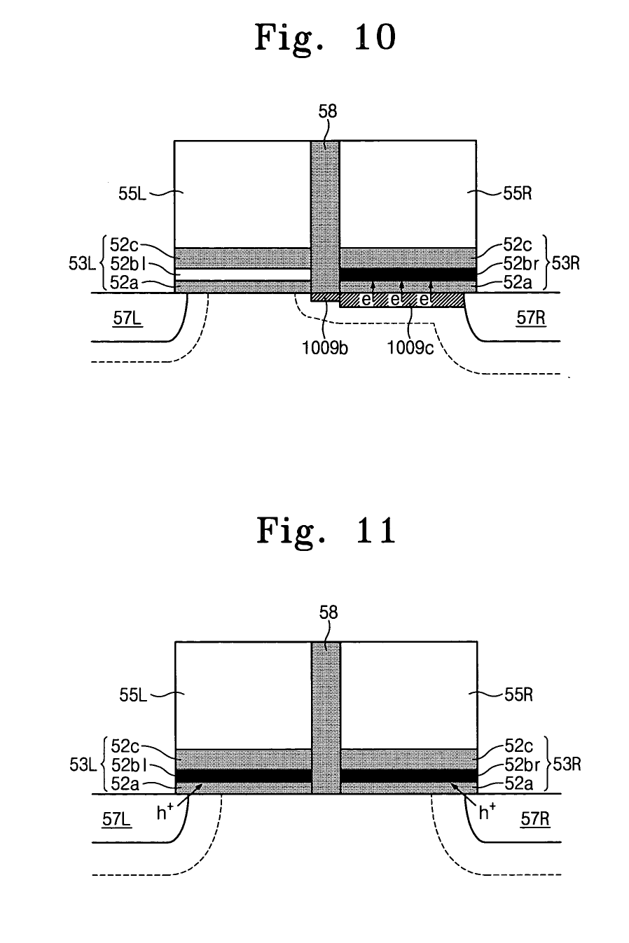

In addition, by appropriately adjusting the voltage applied to the first and second gates 55L and 55R, it may be possible to selectively inject electrons into only one of the two charge-trapping layers 52bl and 52br. More particularly, FIG. 10 illustrates that electrons may be injected into the second charge-trapping layer 52br by a tunneling effect. Referring to FIG. 10, a relatively high voltage in a range of about 10 V to about 20 V (for example, about 15V) is applied to the second gate 55R, so that the electrons in a channel 1009c are injected into the charge-trapping layer 52br through the tunnel oxide layer 52a. A ground voltage, i.e., 0 V, is applied to the junction regions 57L and 57R and to the substrate 51. Meanwhile, a programming prevention voltage (in a range of about 0 V to about 8 V) that is lower than the voltage applied to the second gate 55R may be applied to the first gate 55L. Accordingly, the electrons of the second channel 1009c may penetrate through the tunnel oxide layer 52a and are injected into the charge-trapping layer 52br so that the second memory cell 56R is in the programmed state. The programmed memory cell, for example, has a threshold voltage of about 3 V.

In the meantime, by changing the polarity of the voltage applied to the second gate 55R, e.g., by applying a predetermined voltage in a range of about −20 V to about −10 V (for example, about −15 V) to the second gate 55R, applying 0 V to the junction regions 57L and 57R and to the substrate 51, and applying a predetermined voltage, e.g., a ground voltage (0 V) to the first gate 56L (for example, greater than the voltage applied to the second gate 55R), the holes in the substrate may be injected into the charge-trapping layer 52br through the tunnel oxide layer 52a, or the electrons stored in the charge-trapping layer 52br may be emitted from the charge-trapping layer 52br to the substrate through the tunnel oxide layer 52a. As such, the second memory cell 56R may be erased.

In addition, in a similar manner, if a voltage in a range of about 10 V to about 20 V (for example, about 15 V) is applied to the first gate 55L, and a ground voltage is applied to the second gate 55R, electrons may be injected into the charge-trapping layer 52bl of the first memory cell 56L so that the first memory cell 56L is selectively programmed.

FIG. 11 illustrates that charges may be injected into both the charge-trapping layers 52bl and 52br through band-to-band tunneling. Referring to FIG. 11, a ground voltage is applied to the substrate 51, and a positive voltage in a range of about 3.5 V to about 5.5 V (for example, about 4.5 V) is applied to the junction regions 57L and 57R. Furthermore, a negative voltage in a range of about −3 V to about −1 V (for example, about −3 V) is applied to the first and second gates 55L and 55R. As a result, hot holes generated around the junction regions 57L and 57R, which partially overlap with the gates 55L and 55R, may be injected into the charge-trapping layers 52bl and 52br due to the electric field from the gates through band-to-band tunneling. When holes are injected into the charge-trapping layers 52bl and 52br, the threshold voltages of the corresponding memory cells are reduced.

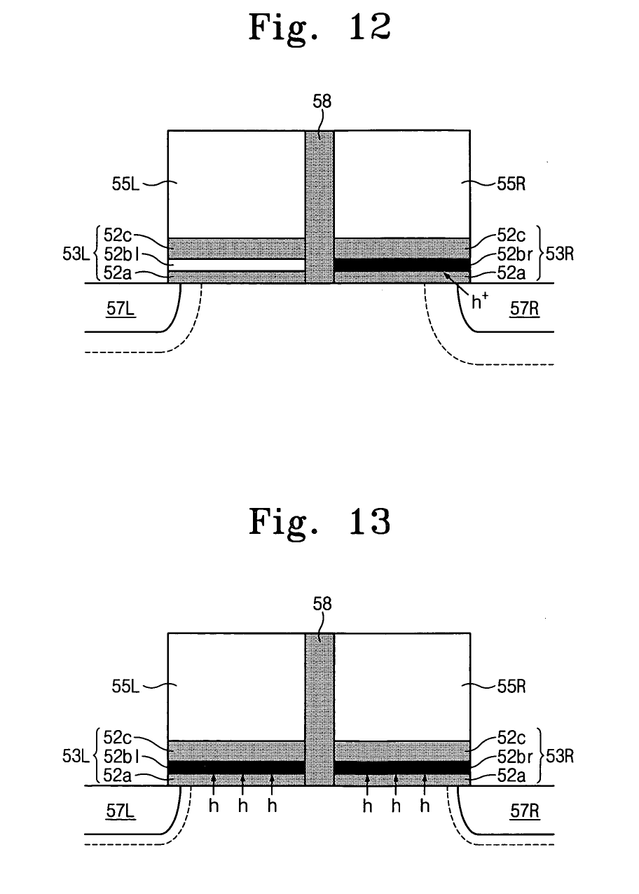

In addition, by adjusting the applied voltages appropriately, it may be possible to inject the holes into the charge-trapping layer of only one of the two memory cells. For example, FIG. 12 illustrates that holes may be selectively injected into the charge-trapping layer 52br of the second memory cell 56R. More particularly, a ground voltage is applied to the first gate 55L, to the first junction region 57L and to the substrate 51. In addition, a negative voltage in a range of about −3 V to about −1 V (for example, about −3 V) is applied to the second gate 55R, and a positive voltage in a range of about 3.5 V to about 5.5 V (for example, about 4.5V) is applied to the second junction region 57R. As a result, hot holes generated around the second junction region 57R, which overlaps with the second gate 55R, may be injected into the second charge-trapping layer 52br due to the electric field from the second gate 55R through band-to-band tunneling. When holes are implanted into the second charge-trapping layer 52br, the threshold voltage of the second memory cell 56R is reduced.

FIG. 13 illustrates another technique whereby holes may be injected into the charge-trapping layers 52bl and 52br of the first and second memory cells 56L and 56R from the substrate 51. Referring to FIG. 13, a ground voltage is applied to the first and second gates 55L and 55R, and each of the junction regions 57L and 57R are provided in a floating state. In addition, a relatively high voltage in a range of about 10 V to about 20 V (for example, about 15 V) is applied to the substrate 51. As a result, holes may be injected into the charge-trapping layers 52bl and 52br through the tunnel oxide layer 52a from the entire surface of the substrate 51. The threshold voltages of the memory cells into which the holes are injected are decreased. In other words, electrons which were stored in the charge-trapping layers 52bl and 52br may be emitted to the substrate through the tunnel oxide layer 52a. Based on the selection of predetermined thicknesses of the memory layers 53L and 53R and/or predetermined materials, either hole injection or electron emission may dominantly occur.

FIGS. 14 to 19 are cross-sectional views illustrating read operations in memory devices according to some embodiments of the present invention. In the drawings, a shaded portion indicates that electrons or holes are injected into (i.e., stored in) the charge-trapping layers 52bl and 52br, and a conductive state of the channel region (i.e., the state that the inversion layer is formed) is represented as a hatched line. When the electrons are injected into the charge-trapping layer 52bl, the memory cell is in an ‘OFF’ state, such that the threshold voltage is about 3 V. On the other hand, if the electrons in the charge-trapping layer 52bl and 52br are emitted, the memory cell in an ‘ON’ state, such that the threshold voltage is about −3 V.

A read operation in memory devices according to some embodiments of the present invention will be set forth below. A ground voltage, i.e., 0 V, is applied to one junction region, i.e., the junction region adjacent to the selected memory cell, and a read voltage Vread, which is higher than the ground voltage, is applied to the other junction region, i.e., the junction region adjacent to the non-selected memory cell. A first control voltage, which is higher than the ‘ON’ state threshold voltage and is lower than the ‘OFF’ state threshold voltage, is applied to the gate of the selected memory cell (i.e., the memory cell adjacent to the junction region to which the ground voltage is applied). A second control voltage, which is higher than the ‘OFF’ state threshold voltage, is applied to the gate of the non-selected memory cell (i.e., the memory cell adjacent to the junction region to which the read voltage Vread is applied). Meanwhile, a ground voltage (or another relatively low voltage which is higher than the ground voltage) is applied to the semiconductor substrate. As a result, based on the state of each memory cell, the corresponding portion of the channel region between the two junction regions may become a low-resistance state (such that current flows well) or a high-resistance state (such that current hardly flows).

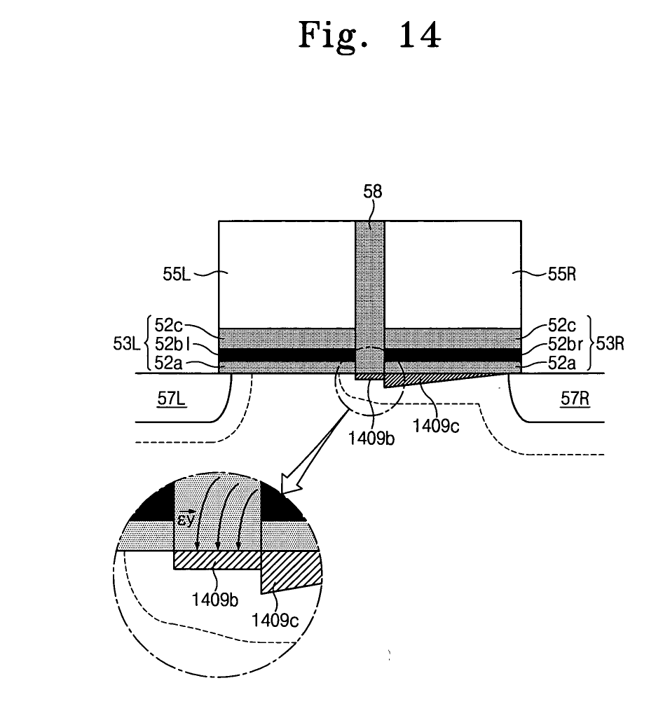

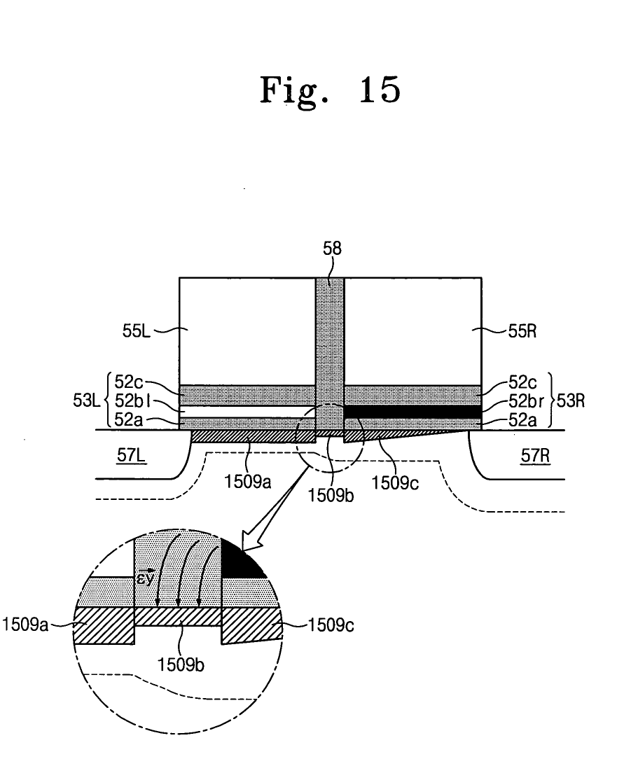

FIGS. 14 and 15 illustrate a read operation for the non-volatile memory device illustrated in FIGS. 5A and 5B. In particular, FIG. 14 illustrates a read operation for the first memory cell 56L, when the first and second memory cells 56L and 56R are in the programmed state (i.e., where electrons have been injected into/stored in both the charge-trapping trapping layers 52bl and 52br of the first and second memory cells 56L and 56R). Meanwhile, FIG. 15 illustrates a read operation for the first memory cell 56L when only the second memory cell 56R is in the programmed state.

Referring now to FIG. 14, in order to read the first memory cell 56L, a channel 1409c is formed under the second memory cell 56R. Likewise, a channel is formed under the first memory cell 56L in order to read the second memory cell 56R. In order to form the inversion layer channel 1409c under the second memory cell 56R, a voltage in a range of about 2 V to about 6 V( for example, about 4 V) is applied to the second gate 55R, and a voltage in a range of about 0.5 V to about 1.5 V (for example, about 1 V) is applied to the second junction region 57R. A ground voltage is applied to the first gate 55L of the first memory cell 56L and the first junction region 57L in order to read the first memory cell 56L. Also, a ground voltage or a relatively low positive voltage in a range of about 0.3 V to about 0.6 V (for example, a voltage of about 0.4 V to about 0.5 V) is applied to the substrate 51.

Since a voltage of about 4 V is applied to the second gate 55R of the second memory cell 56R (which has a threshold voltage of about 3 V), a channel 1409c is formed under the memory cell 56R. In addition, a channel 1409b is formed under the separate insulating layer 58 due to the coupling effect of the fringe electrical field (ε_{y}) resulting from the voltage applied to the second gate 55R. However, since a ground voltage is applied to the first gate 55L of the first memory cell 56L (which also has a threshold voltage of about 3 V), a channel is not formed under the first memory cell 56L. In other words, an inversion layer channel is not continuously formed between the two junction regions 57L and 57R. Therefore, the channel region between the two junction regions 57L and 57R is in a high-resistance state, so that current may hardly flow therebetween. In addition, it may be desirable to apply a ground voltage (i.e., 0 V) to the first junction region 57L adjacent to the selected memory cell 56L and a voltage which is higher than the ground voltage (for example, 1 V) to the second junction region 57R adjacent to the non-selected memory cell 56R. This may be desirable because drain induced barrier lowering (DIBL) effects may be reduced and/or prevented by minimizing the voltage applied to the junction region of the memory device, and thus, the short channel effect may be reduced. Moreover, when a relatively low positive voltage is applied to the substrate 51, the width of a depletion region between the substrate 51 and the junction region may also be reduced, which may further improve short channel characteristics.

Similarly, in order to read the second memory cell 56R, the voltages applied to the first gate 55L and the first junction region 57L can be interchanged with the voltage applied to the second gate 55R and the second junction region 57R. That is, a ground voltage is applied to the second gate 55R and the second junction region 57R, and a voltage in a range of about 2 V to about 6 V (for example, about 4 V) is applied to the first gate 55L. Moreover, a voltage in a range of about 0.5 V to about 1.5 V (for example, about 1 V) is applied to the second junction region 57L. In this case, an inversion layer channel is formed under the first memory cell 56L, but a channel is not formed under the second memory cell 56R.

FIG. 15 illustrates a read operation for the first memory cell 56L when the second memory cell 56R is in a programmed state and the first memory cell 56L is in an erased state. Referring to FIG. 15, in order to form a channel 1509c under the second memory cell 56R, a voltage in a range of about 2 V to about 6 V (for example, about 4 V) is applied to the second gate 55R, and a voltage in a range of about 0.5 V to about 1.5 V (for example, about 1 V) is applied to the second junction region 57R. To read the first memory cell 56L, a ground voltage is applied to the gate 55L of the first memory cell 56L and the first junction region 57L. Also, a ground voltage or a relatively low positive voltage, e.g., about 0.3 V to about 0.6 V (for example, a voltage of about 0.4 V to about 0.5 V) is applied to the substrate 51. Since the first memory cell 56L is in the erased state and has a threshold voltage of about −3 V, a channel 1509a is formed under the first memory cell 56L. In addition, as described above, a channel 1509c is formed under the second memory cell. Also, a channel 1509b is formed under the separate insulating layer 58, due to the coupling capacitance. As a result, an inversion layer channel is formed extending between the two junction regions 57L and 57R to provide a low-resistance state, so that current may flow therebetween.

Similarly, in order to read the second memory cell 56R, the voltages applied to the first gate 55L and the first junction region 57L may be interchanged with the voltage applied to the second gate 55R and the second junction region 57R. More particularly, a ground voltage is applied to the second gate 55R and the second junction region 57R, and a voltage in a range of about 2 V to about 6 V (for example, about 4 V) is applied to the first gate 55L, and a voltage in a range of about 0.5 V to about 1.5 V (for example, about 1 V) is applied to the first junction region 57L. In this case, an inversion layer channel is formed under the first memory cell 56L but not under the second memory cell 56R, because the threshold voltage of the programmed second memory cell 56R is about 3 V.

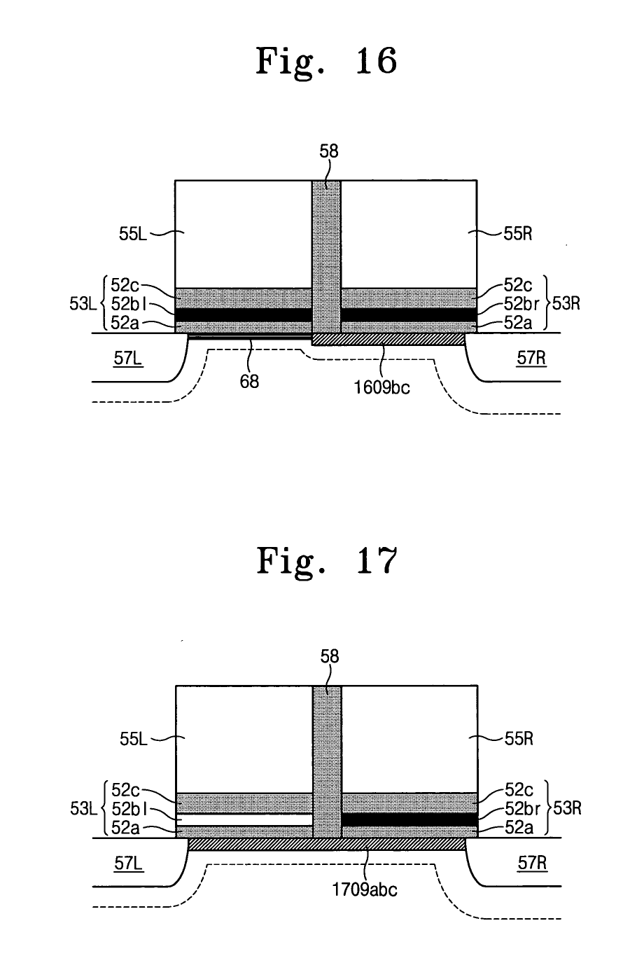

FIGS. 16 and 17 illustrate a read operation for the non-volatile memory device of FIGS. 6A and 6B. In particular, FIG. 16 illustrates a read operation for a memory cell in the programmed state, where electrons have been injected into/stored in both the charge-trapping layers 52bl and 52br of the first and second memory cells 56L and 56R. Meanwhile, FIG. 17 illustrates a read operation for the memory cell when only the second memory cell 56R is in the programmed state.

First, referring to FIG. 16, a voltage in a range of about 2 V to about 6 V (for example, about 4 V) is applied to the second gate 55R, and a voltage in a range of about 0.5 V to about 1.5 V (for example, about 1 V) is applied to the second junction region 57R. A ground voltage is applied to the first gate 55L of the first memory cell 56L and to the first junction region 57L. Also, a ground voltage or a relatively low positive voltage in a range of about 0.5 V to about 1.5 V (for example, about 1 V) is applied to the substrate 51.

The doping concentration of the impurity diffusion layer 68 may be selected such that a channel is not formed under the memory cell when a ground voltage is applied to the gate of the memory cell in the erased state. Meanwhile, because the impurity diffusion layer 68 is lightly doped with impurities and extends between the two junction regions 57L and 57R, the voltage applied to the second gate 55R may be reduced in comparison with the memory device of FIG. 14.

Since the impurity diffusion layer 68 is formed under the second memory cell and a voltage (e.g., about 4 V) higher than the threshold voltage is applied to the second gate 55R, an inversion layer channel 1609bc is formed in the portions of the channel region under the separate insulating layer 58 and under the second gate 55R. Meanwhile, although the impurity diffusion layer 68 extends across the portion of the channel region under the first gate 55L, a channel is not formed under the first gate 55L, because a ground voltage (which is lower than the programmed-state threshold voltage of 3 V) is applied to the first gate 55L. Therefore, the channel 1609bc is discontinuously formed between the junction regions 57L and 57R to provide a high-resistance state, so that current may not flow well therebetween.

It may be desirable to apply the ground voltage (i.e., 0 V) to the junction region 57L adjacent to the selected memory cell 56L, and to apply a higher voltage to the junction region 57R adjacent to the non-selected memory cell 56R, because DIBL effects can be reduced and/or prevented by minimizing the voltage applied to the junction region of the memory device. Thus, short channel effects may be reduced. In addition, when a relatively low positive voltage is applied to the substrate 51, the width of a depletion region between the substrate and the junction region may also be reduced, so as to further improve short channel characteristics.

FIG. 17 illustrates a read operation when the first memory cell (the left memory cell) is in an erased state and the second memory cell (the right memory cell) is in a programmed state. Referring to FIG. 17, a voltage in a range of about 2 V to about 6 V (for example, about 4 V) is applied to the second gate 55R, and a voltage in a range of about 0.5 V to about 1.5 V (for example, about 1 V) is applied to the second junction region 57R. A ground voltage is applied to the first gate 55L of the first memory cell 56L and to the first junction region 57L. Also, a ground voltage or a relatively low positive voltage in a range of about 0.5 V to about 1.5 V (for example, about 1 V) is applied to the substrate 51. Therefore, since the first memory cell 56L is in the erased state so that its threshold voltage is about −3 V, an inversion layer channel 1709abc is formed under the first memory cell 56L as well as under the second memory cell 56R and the separate insulating layer 58. That is, the channel 1709abc is formed extending across the channel region between the two junction regions 57L and 57R. Consequently, the channel is continuously formed between the junction regions 57L and 57R to provide a low-resistance state, so that current may flow well therebetween.

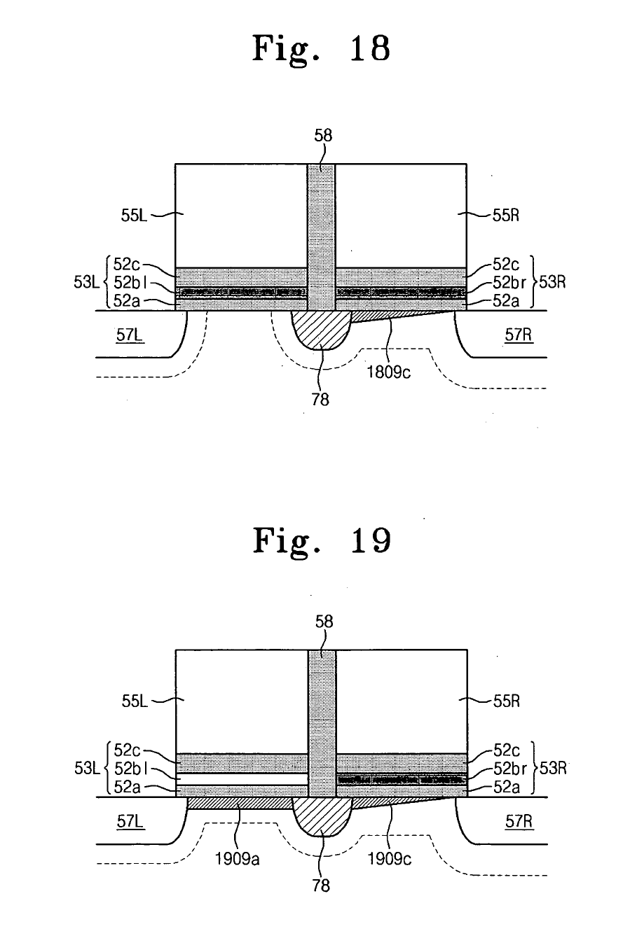

FIGS. 18 and 19 illustrate a read operation for the non-volatile memory device of FIGS. 7A and 7B. In particular, FIG. 18 illustrates a read operation for the first memory cell when the first and second memory cells 56L and 56R are both in the programmed state (where electrons have been implanted into/stored in both the charge-trapping layers 52bl and 52br of the first and second memory cells 56L and 56R). Meanwhile, FIG. 19 illustrates a read operation for the first memory cell 56L when only the second memory cell 56R is in the programmed state.

First, referring to FIG. 18, in order to form an inversion layer channel 1809c under the second memory cell 56R, a voltage in a range of about 2 V to about 6 V (for example, about 4 V) is applied to the second gate 55R, and a voltage in a range of about 0.5 V to about 1.5 V (for example, about 1 V) is applied to the second junction region 57R. A ground voltage is applied to the gate 55L of the first memory cell 56L and to the first junction region 57L. Also, a ground voltage or a relatively low positive voltage in a range of about 0.5 V to about 1.5 V (for example, about 1 V) is applied to the substrate 51.

Because the voltage of about 4 V is applied to the second gate 55R of the second memory cell 56R (which has a threshold voltage of about 3 V), a channel 1809c is formed in the portion of the channel region under the second memory cell 56R. Also, the impurity diffusion region 78 is disposed under the separate insulating layer 58. However, since the ground voltage is applied to the first gate 55L of the first memory cell 56L (which has a threshold voltage of about 3 V), a channel is not formed in the portion of the channel region under the first memory cell 56L. In other words, a channel is discontinuously formed between the junction regions 57L and 57R to provide a high-resistance state, so that current cannot flow well therebetween. It may be desirable for a ground voltage (i.e., 0 V) to be applied to the junction region 57L adjacent to the selected memory cell 56L, and a higher voltage to be applied to the junction region 57R adjacent to the non-selected memory cell 56R, as DIBL effects can be reduced and/or prevented by minimizing the voltage applied to the junction region of the memory device. Thus, short channel effects may be reduced. In addition, when a relatively low positive voltage is applied to the substrate 51, the width of a depletion region between the substrate and the junction region may be reduced, so as to further improve short channel characteristics.

FIG. 19 illustrates a read operation on the first memory cell 56L in which only the second memory cell is in a programmed state (i.e., charges are trapped in the charge-trapping layer 52br) and the first memory cell 56L is in an erased state. Referring to FIG. 19, in order to form an inversion layer channel 1909c under the second memory cell 56R, a voltage in a range of about 2 V to about 6 V (for example, about 4 V) is applied to the second gate 55R, and a voltage in a range of about 0.5 V to about 1.5 V (for example, about 1 V) is applied to the second junction region 57R. A ground voltage is applied to the first gate 55L of the first memory cell 56L and to the first junction region 57L for reading the first memory cell 56L. Also, a ground voltage or a relatively low positive voltage in a range of about 0.4 V to about 0.5 V (for example, about 1 V) is applied to the substrate 51. Therefore, since the first memory cell 56L is in the erased state (so that its threshold voltage is about −3 V), an inversion layer channel is formed under the first memory cell 56L as well as the second memory cell 56R and the separate insulating layer 58. That is, channels 1909a and 1909c are connected via the impurity diffusion region 78. Consequently, an inversion layer channel is formed in the channel region extending between the junction regions 57L and 57R to provide a low-resistance state, so that current may flow therebetween.

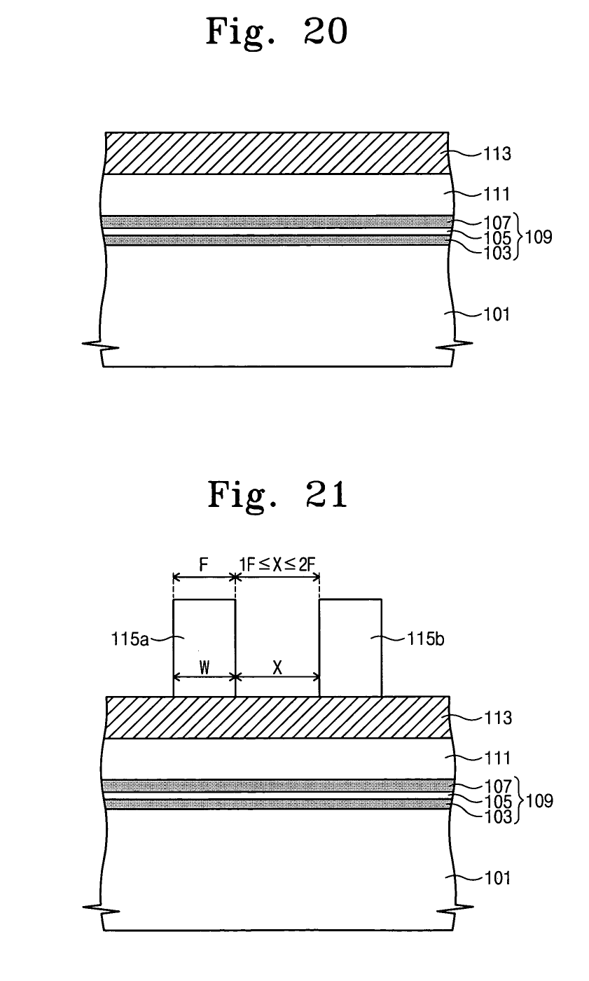

Methods for manufacturing an n-channel memory device as illustrated in FIGS. 5-7 will be described hereinafter. More particularly, a method for forming the non-volatile memory device of FIGS. 5A and 5B will be described with reference to FIGS. 20 to 26.

Referring now to FIG. 20, a p-type substrate 101 is provided. After a device isolation process is performed any of a number of well-known methods, a multi-layer memory layer 109 including a charge-trapping layer 105 therein is formed on the substrate 101. The memory layer 109 includes a tunnel oxide layer 103, a charge trapping layer 105, and a blocking insulating layer 107 stacked in sequence. The tunnel oxide layer 103 may be formed to a thickness of about 35 Å to about 40 Å using a thermal oxidation process or any well-known thin film deposition process. The charge-trapping layer 105 may be formed of a nitride layer to a thickness of about 70 Å to about 150 Å using any well-known thin film deposition process. The blocking insulating layer 107 may be formed of an oxide layer to a thickness of about 100 Å to about 200 Å using a well-known thin film deposition process as well.

A conductive or insulating material including a charge-trapping region therein may be used as the charge-trapping layer 105, instead of the nitride layer. For instance, the charge-trapping layer 105 may employ an insulator with a relatively high charge trap density, such as an aluminum oxide layer (Al₂O₃), a hafnium oxide layer (HfO), a hafnium-aluminum oxide layer (HfAlO), a hafnium silicon oxide layer (HfSiO), or the like. In addition, doped polysilicon, metal, or nanocrystals thereof may be used as the charge-trapping layer 105.

The blocking insulating layer 107 may employ an insulator with a relatively high dielectric constant, such as an aluminum oxide layer (Al₂O₃), a hafnium oxide layer (HfO), a hafnium-aluminum oxide layer (HfAlO), a hafnium silicon oxide layer (HfSiO), or the like, instead of the oxide layer.

Before forming the memory layer 109, it may be possible to form the impurity diffusion layer of the memory device in FIGS. 6A and 6B by implanting impurity ions into the substrate of an opposite conductive type than the substrate 101. For example, in forming an n-channel memory cell, the impurity diffusion layer may be formed by implanting arsenic or phosphor ions at a predetermined energy level in a range of about 30 keV to about 50 keV, with a dose of about 1×10¹² to about 5×10¹³ atoms/cm². Meanwhile, in forming a p-channel memory cell, the impurity diffusion layer may be formed by implanting boron ions under similar conditions as described above.

A conductive layer 111, which may be used to form a gate, is formed on the memory layer 109. The conductive layer, for example, may be formed of polysilicon doped with impurities. To provide a memory cell having a negative threshold voltage, the conductive layer 111 may be formed of a metal material or polysilicon in which the doping concentration is appropriately adjusted, instead of implanting the impurity ions into the substrate. In addition, it may be possible to control the threshold voltage of the memory cell using a combination of an ion implantation for the impurity diffusion layer and an ion implantation for gate-doping.

Thereafter, a hard mask layer 113 is formed on the conductive layer 111. The hard mask layer 113, for example, may be formed of a silicon nitride layer or a silicon oxide layer through any well-known thin film deposition process.

Referring to FIG. 21, a photolithography process is performed so as to form dummy patterns 115a and 115b on the hard mask layer 113. The dummy pattern 115a and 115b may be formed of a photoresist pattern or a material pattern having a relatively high etch selectivity with respect to the hard mask 113, e.g., an undoped polysilicon pattern.

Each dummy pattern 115a and 115b may be formed such that its linewidth W may be a minimum linewidth F that may be achieved by the photolithography process. In addition, the dummy patterns 115a and 115b are formed such that the distance X between neighboring dummy patterns 115a and 115b is greater than the minimum linewidth, but is less than two times the minimum linewidth (i.e., F≧X≧2*F). The distance X between the neighboring dummy patterns may be determined according to a final desired thickness of the target gate and/or a desired distance between neighboring gates.

Referring to FIG. 22, insulating spacers 117a and 117b are formed on sidewalls of each dummy pattern 115a and 115b. The insulating spacers 117a and 117b may be formed by depositing an insulating material and performing an etchback process. The insulating spacers 117a and 117b are formed of a material having an etch selectivity with respect to the hard mask layer 113. For instance, in forming the hard mask layer 113 as a silicon oxide layer, the spacers 117a and 117b may be formed of silicon nitride. Alternatively, in forming the hard mask layer 113 of silicon nitride, the spacers 117a and 117b may be formed of silicon oxide.

The width L of each spacer 117a and 117b is less than a half the distance X between the dummy patterns (i.e., L<X/2). Therefore, the distance D between the neighboring spacers formed on the neighboring dummy patterns, e.g., the distance between adjacent spacers of the dummy pattern 115a and the dummy pattern 115b, is less than the minimum linewidth F. The distance between the neighboring spacers determines a minimum distance between the memory cells, which will be more fully described below. Therefore, it may be possible to form two memory cells separated by a distance less than the minimum linewidth that may be achieved by current photolithography processes.

Referring to FIG. 23, after removing the dummy patterns 115a and 115b, the exposed hard mask layer 113 is etched using the spacers 117a and 117b as an etch mask to form hard mask layer patterns 113a and 113b. The hard mask layer patterns 113a and 113b may have widths that are substantially identical to the width L of the spacers.

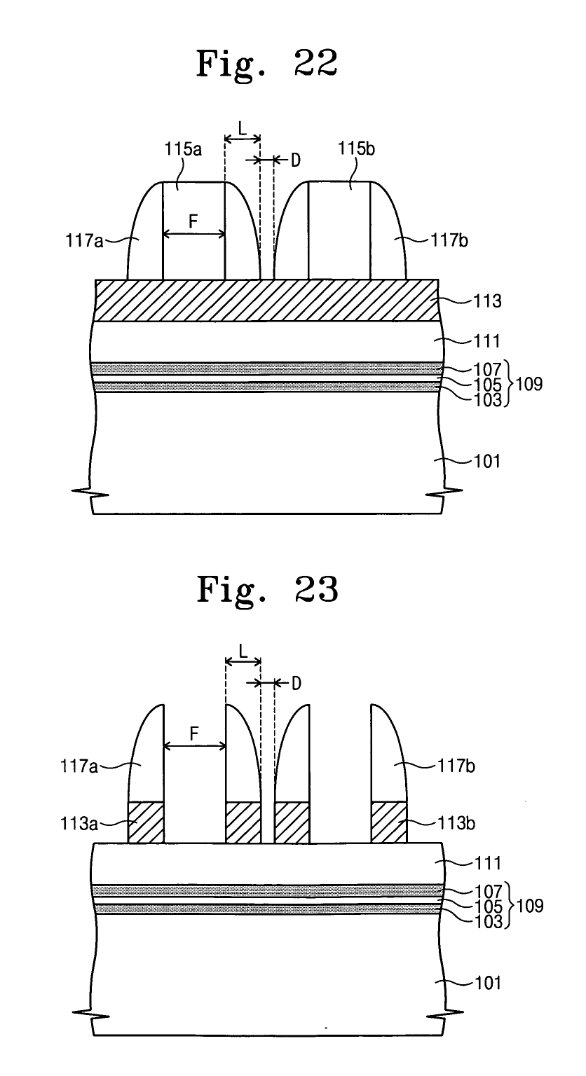

Referring to FIG. 24, after removing the spacers 117a and 117b, the conductive layer 111 and the memory layer 109 are etched using the hard mask layer patterns 113a and 113b as an etch mask to thereby form memory cells 118a and 118b including conductive layer gates 111a and 111b and memory layer patterns 109a and 109b. Two neighboring memory cells 118a and 118b may constitute a unit memory cell. The distance between the neighboring memory cells 118a and 118b is less than the thickness of the memory layer patterns 109a or 109b. Moreover, the distance between the neighboring memory cells 118a and 118b is less than the minimum linewidth that may be achieved by current photolithography processes.

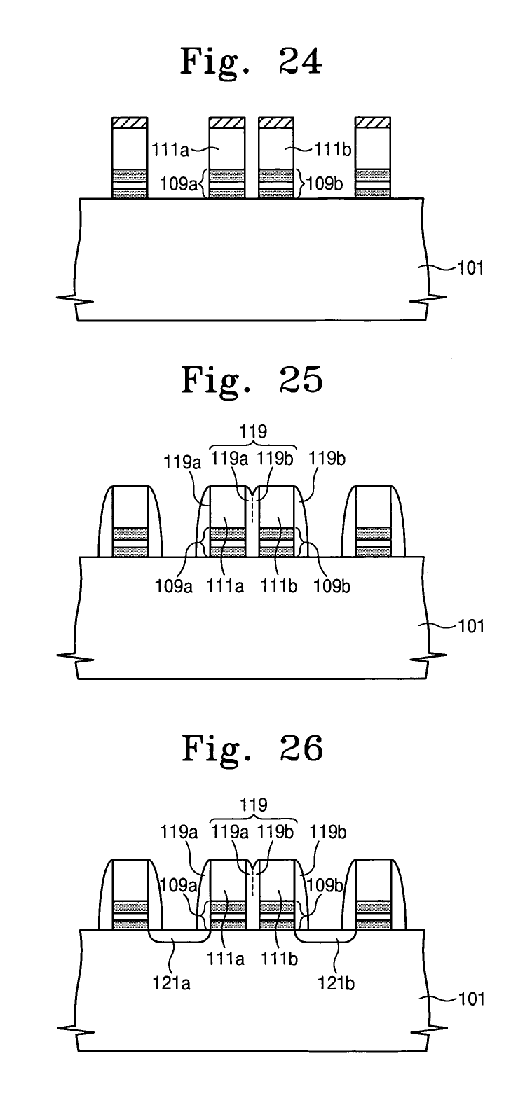

Referring to FIG. 25, an insulating material which does not include a charge-trapping layer is deposited and is etched back so as to form spacers 119a and 119b on sidewalls of each memory cell 118a and 118b. At this time, since the distance D between the two neighboring memory cells 118a and 118b is relatively narrow, the neighboring insulating spacers 119a and 119b may fill the space between the two neighboring memory cells 118a and 118b to form a separate insulating layer 119.

Referring to FIG. 26, an impurity ion implantation process is performed to form junction regions 121a and 121b acting as a source and a drain in the substrate disposed on opposite sides of the two memory cells 118a and 118b, which are electrically insulated from each other by the separate insulating layer 119. The junction regions 121a and 121b may be formed by implanting phosphor ions at a predetermined energy level in a range of about 30 keV to about 50 keV, with a dose of about 1×10¹⁵ to about 5×10¹⁵ atoms/cm². In forming a p-channel memory cell, boron ions may be implanted under similar conditions. Thereafter, processes for forming an interlayer insulating layer, interconnections, and so forth may be performed.

In some embodiments, before forming the memory layer 109, the impurity diffusion layer of the memory device of FIGS. 6A and 6B may be formed by implanting impurity ions into the substrate 101 which are of an opposite conductive type than the substrate 101, in order to provide an n-channel memory cell having a negative threshold voltage. For instance, in forming the n-channel memory cell, the impurity diffusion layer may be formed by implanting arsenic or phosphor ions at a predetermined energy level in a range of about 30 keV to about 50 keV, with a dose of about 1×10¹² to about 1×10¹³ atoms/cm². In forming a p-channel memory cell, boron ions may be implanted under similar conditions.

Alternatively, the gate conductive layer 111 may be formed of a metal layer, a doped polysilicon layer in which a doping concentration is appropriately adjusted, and/or multiple layers including the metal and/or the polysilicon.

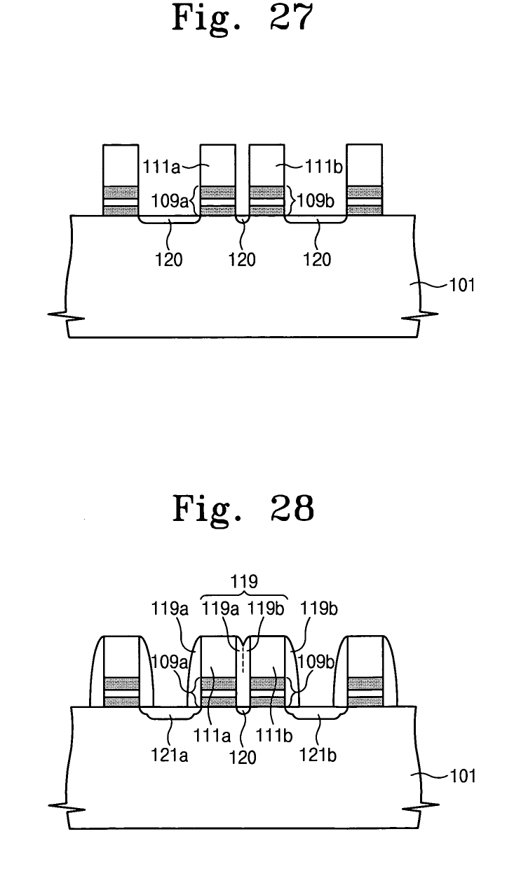

A method for forming the memory device of FIGS. 7A and 7B will now be described with reference to FIGS. 27 and 28.

Referring to FIG. 27, after performing the processes illustrated above in FIGS. 20 to 24, a process for implanting a relatively low concentration of impurity ions is performed. Accordingly, a low concentration impurity diffusion region 120 is formed in the substrate between neighboring memory cells 118a and 118b. The low concentration impurity diffusion region 120 is formed between adjacent sidewalls of the memory cells 118a and 118b. The low concentration impurity diffusion region 120 may be formed by implanting arsenic ions at a predetermined energy level in a range of about 10 keV to about 30 keV with a dose of about 5×10¹⁴ to about 1×10¹⁵ atoms/cm². In forming a p-channel memory cell, boron ions may be implanted under the similar conditions.

Referring to FIG. 28, an insulating material which does not include the charge-trapping layer is deposited and is etched back so as to form spacers 119a and 119b on sidewalls of each memory cell 118a and 118b. At this time, since the distance D between the two neighboring memory cells 118a and 118b is relatively narrow, the neighboring insulating spacers 119a and 119b fill the space between the two neighboring memory cells 118a and 118b to form a separate insulating layer 119. A high concentration impurity ion implantation process for forming source/drain regions is then performed, to form junction regions 121a and 121b acting as a source and a drain in the substrate on opposite sides of the two memory cells 118a and 118b (which are insulated from each other by the separate insulating layer 119). The junction regions 121a and 121b may be formed by implanting phosphor ions at a predetermined energy level in a range of about 30 keV to about 50 keV with a dose of about 1×10¹⁵ to about 5×10¹⁵ atoms/cm². In forming a p-channel memory cell, boron ions may be implanted under similar conditions as above.

Accordingly, a memory device according to some embodiments of the present invention includes two control gates between the drain and the source that are physically isolated by an insulating layer that does not include a charge-trapping site, and a memory layer including a charge-trapping layer therein between each control gate and the channel region of the substrate. Therefore, it may be possible to vary the threshold voltage of the memory device so that electrons or holes may be selectively injected into/emitted from each charge-trapping layer by applying a predetermined voltage to the drain, the source, the substrate and/or each gate. In addition, the two memory cells are electrically isolated from each other by a relatively thin separate insulating layer, so that it may be possible to implement highly-integrated memory devices.

While the present invention has been particularly shown and described with reference to exemplary embodiments thereof, it will be understood by those of ordinary skill in the art that various changes in form and details may be made therein without departing from the spirit and scope of the present invention as defined by the following claims and their equivalents.

That which is claimed:

1. A non-volatile integrated circuit memory device, comprising:
a substrate including first and second source/drain regions therein and a channel region therebetween;
a first memory cell on the channel region adjacent the first source/drain region, the first memory cell comprising a first conductive gate on the channel region and a first multi-layered charge storage structure therebetween;
a second memory cell on the channel region adjacent the second source/drain region, the second memory cell comprising a second conductive gate on the channel region and a second multi-layered charge storage structure therebetween; and
a single-layer insulating layer on the channel region extending between the first and second memory cells along sidewalls thereof

2. The device of claim 1, wherein the single-layer insulating layer separates the first and second conductive gates by a distance of less than a thickness of the first multi-layered charge storage structure.

3. The device of claim 1, wherein a portion of the single-layer insulating layer between the first and second multi-layered charge storage structures has a dielectric strength greater than a portion thereof between the first and second conductive gates.

4. The device of claim 1, wherein the single-layer insulating layer does not comprise a charge-trapping layer.

5. The device of claim 1, wherein the channel region comprises a first portion adjacent the first multi-layered charge storage structure configured to be controlled by the first conductive gate, a second portion adjacent the second multi-layered charge storage structure configured to be controlled by the second conductive gate, and a third portion between the first and second portions configured to be controlled by the first conductive gate and/or by the second conductive gate.

6. The device of claim 1, wherein the channel region comprises an impurity diffusion region along a surface thereof adjacent the single-layer insulating layer between a first portion of the channel region configured to be controlled by the first conductive gate and a second portion of the channel region configured to be controlled by the second conductive gate.

7. The device of claim 6, wherein the impurity diffusion region comprises a same conductive type as the first and second source/drain regions.

8. The device of claim 6, wherein an impurity concentration of the impurity diffusion region is less than that of the first and second source/drain regions.

9. The device of claim 8, wherein the impurity concentration of the impurity diffusion region is in a range of about 5×10¹⁴ to about 1×10¹⁵ atoms per square centimeter, and wherein the impurity concentration of the first and second source/drain regions is in a range of about 1×10¹⁵ to about 5×10¹⁵ atoms per square centimeter.

10. The device of claim 6, wherein the first and second source/drain regions extend into the substrate to a greater depth than the impurity diffusion region relative to the surface of the substrate.

11. The device of claim 6, wherein the impurity diffusion region further extends along a surface of the channel region from the first source/drain region to the second source/drain region.

12. The device of claim 11, wherein an impurity concentration of the impurity diffusion region is in a range of about 1×10¹² to 1×10¹³ atoms per square centimeter.

13. The device of claim 1, wherein the first and second multi-layered charge storage structures respectively comprise first and second oxide-nitride-oxide (ONO) layers comprising a tunnel oxide layer on the channel region, a nitride charge trapping layer on the tunnel oxide layer, and a blocking insulating layer on the nitride charge trapping layer.

14. The device of claim 13, wherein a thickness of the tunnel oxide layer is about 35 to about 40 Angstroms, wherein a thickness of the charge trapping layer is about 70 to about 150 Angstroms, and wherein a thickness of the blocking insulating layer is about 100 to about 200 Angstroms.

15. The device of claim 1, wherein the single-layer insulating layer comprises a different material than the first and second multi-layered charge storage structures.

16. The device of claim 1, wherein the single-layer insulating layer comprises silicon oxide.

17. A method of fabricating a non-volatile integrated circuit memory device, the method comprising:
forming a charge storage layer on a substrate;
forming a conductive layer on the charge storage layer;
patterning the conductive layer and the charge storage layer to define a first memory cell comprising a first conductive gate on a first multi-layered charge storage structure and to define a second memory cell comprising a second conductive gate on a second multi-layered charge storage structure; and
forming a single-layer insulating layer on the substrate between the first and second memory cells extending along sidewalls thereof.

18. The method of claim 17, wherein patterning the conductive layer and the charge storage layer comprises:
forming first and second dummy patterns on the conductive layer;
forming spacers on adjacent sidewalls of the first and second dummy patterns, wherein the spacers have a width of less than half of a distance between the first and second dummy patterns; and
patterning the conductive layer and the charge storage layer using the spacers as a mask to form the first memory cell and the second memory cell.

19. The method of claim 18, wherein forming the first and second dummy patterns comprises:
forming a dummy layer on the conductive layer; and
photolithographically patterning the dummy layer to form the first and second dummy patterns,
wherein the distance between the first and second dummy patterns is greater than a minimum width that can be achieved by the photolithographically patterning, but is less than twice the minimum width.

20. The method of claim 19, further comprising:
forming a hard mask layer on the conductive layer prior to forming the dummy layer thereon; and
removing the first and second dummy patterns after forming the spacers on the adjacent sidewalls thereof,
wherein patterning the conductive layer and the charge storage layer comprises patterning the hard mask layer using the spacers as a mask to form first and second hard mask patterns, and patterning the conductive layer and the charge storage layer using the first and second hard mask patterns as a mask to form the first and second memory cells separated by a distance of less than the minimum width that can be achieved by the photolithographically patterning.

21. The method of claim 17, wherein forming the charge storage layer comprises:
forming a tunnel oxide layer on the substrate;
forming a nitride charge trapping layer on the tunnel oxide layer; and
forming a blocking insulating layer on the nitride charge trapping layer.

22. The method of claim 21, wherein forming the single-layer insulating layer comprises forming a silicon oxide insulating layer.

23. The method of claim 17, further comprising:
respectively forming first and second source/drain regions in the substrate on opposite sides of the first and second charge storage layers to define a channel region therebetween,
wherein the first conductive gate controls a first portion of channel region adjacent the first multi-layered charge storage structure, wherein the second conductive gate controls a second portion of the channel region adjacent the second multi-layered charge storage structure, and wherein the first and/or the second conductive gate controls a third portion of the channel region between the first and second portions.

24. The method of claim 17, further comprising the following prior to forming the single-layer insulating layer:
implanting impurities of a first conductive type into the substrate between the first and second memory cells using the first and second conductive gates as a mask to form an impurity diffusion region therebetween.

25. The method of claim 24, further comprising the following after forming the single-layer insulating layer between the first and second memory cells:
implanting impurities of the first conductive type into the substrate on opposite sides of the first and second gates using the first and second conductive gates and the single-layer insulating layer as a mask to form first and second source/drain regions.

26. The method of claim 25, wherein the first and second source/drain regions extend into the substrate to a greater depth than the impurity diffusion region relative to a surface of the substrate.

27. The method of claim 25, wherein an impurity concentration of the impurity diffusion region is less than that of the first and second source/drain regions.

28. The method of claim 17, further comprising the following prior to forming the charge storage layer:
implanting impurities of a first conductive type into the substrate to form an impurity diffusion layer extending along a surface of the substrate.

29. The method of claim 28, wherein forming the charge storage layer comprises forming the charge storage layer on the impurity diffusion layer, and further comprising the following after forming the single-layer insulating layer:
implanting impurities of the first conductive type into the substrate on opposite sides of the first and second memory cells using the first and second conductive gates and the single-layer insulating layer as a mask to respectively form first and second source/drain regions contacting the impurity diffusion layer on opposite sides thereof and extending into the substrate beyond the impurity diffusion layer.

30. The method of claim 17, wherein forming the single-layer insulating layer comprises:
forming the single-layer insulating layer of a different material than the first and second multi-layered charge storage structures.

31. The method of claim 17, wherein forming the single-layer insulating layer comprises:
forming the single-layer insulating layer having a first portion of a first dielectric strength between the first and second conductive gates and a second portion of a second dielectric strength between the first and second multi-layered charge storage structures, wherein the second portion of the single-layer insulating layer has greater a dielectric strength than the first portion thereof.

32. The method of claim 17, wherein the single-layer insulating layer does not comprise a charge-trapping layer.

33. The method of claim 17, wherein forming the single-layer insulating layer comprises:
forming the single-layer insulating layer between the first and second memory cells to separate the first and second conductive gates by a distance of less than a thickness of the charge storage layer.

34. A depletion-mode non-volatile integrated circuit memory device, comprising:
a substrate including first and second source/drain regions therein and a channel region therebetween;
an impurity diffusion region extending along a surface of the channel region from the first source/drain region to the second source/drain region;
a first memory cell on the channel region adjacent the first source/drain region, the first memory cell comprising a first conductive gate on the impurity diffusion region and a first charge storage structure therebetween;
a second memory cell on the channel region adjacent the second source/drain region, the second memory cell comprising a second conductive gate on the impurity diffusion region and a second charge storage structure therebetween; and
an insulating layer on the channel region extending between the first and second memory cells along sidewalls thereof.

35. A non-volatile memory device comprising:
spaced apart a first junction region and a second junction region formed in a semiconductor substrate and defining a channel region therebetween; and
a first memory cell and a second memory cell formed on the channel region of the semiconductor substrate with interposing a non-charge trapping insulating layer therebetween,
wherein each of the first and second memory cells comprises:
a memory layer including a tunnel oxide layer, a charge-trapping layer and a blocking insulating layer stacked on the channel region in sequence; and
a gate formed on the memory layer.

36. The non-volatile memory device of claim 35, wherein the width of the non-charge trapping insulating layer interposed between the first and second memory cells is equal to or less than a minimum linewidth.

37. The non-volatile memory device of claim 35, wherein the width of the non-charge trapping insulating layer is less than the thickness of the memory layer.

38. The non-volatile memory device of claim 35, wherein the non-charge trapping insulating layer is a silicon oxide layer.

39. The non-volatile memory device of claim 35, further comprising an impurity diffusion region of which the depth is different from the depths of the first and second junction regions, the impurity diffusion region being formed by implanting an impurity into the channel region of the semiconductor substrate under the non-charge trapping insulating layer, the conductive type of the impurity being identical to that of the junction region

40. The non-volatile memory device of claim 39, wherein the impurity concentration of the impurity diffusion region is lower than the impurity concentrations of the first and second junction regions.

41. The non-volatile memory device of claim 35, wherein the charge-trapping layer is a material layer having a trapping region.

42. The non-volatile memory device of claim 35, further comprising an impurity diffusion layer by implanting an impurity of which a conductive type is identical to that of the junction region into a surface of the channel region of the semiconductor substrate.

43. The non-volatile memory device of claim 42, wherein the impurity concentration of the impurity diffusion region is lower than the impurity concentrations of the first and second junction regions.

44. The non-volatile memory device of claim 43, wherein the depth of the impurity diffusion layer is less than the junction depths of the first and second junction regions.

45. The non-volatile memory device of claim 35, wherein the channel region includes:
a first channel region under the first memory cell configured to be controlled by a gate of the first memory cell;
a second channel region under the second memory cell configured to be controlled by a gate of the second memory cell; and
a third channel region under the non-charge trapping insulating layer configured to be controlled by the gate of the first or second memory cell.

46. A method of reading out data in the non-volatile memory device of claim 33 comprising:
applying a ground voltage to one junction region, and a read voltage higher than the ground voltage to the other junction region;
applying a first control voltage to a gate of a memory cell adjacent to the junction region to which the ground voltage is applied, and applying a second control voltage to a gate of a memory cell adjacent to the junction region to which the read voltage is applied, wherein the first control voltage is greater than an ‘ON’ state threshold voltage and less than an ‘OFF’ state threshold voltage, and a second control voltage is greater than an ‘OFF’ state threshold voltage and less than an ‘ON’ state threshold voltage; and
applying a ground voltage or a low voltage which is higher than the ground voltage to the semiconductor substrate.

47. A method for operating the non-volatile memory device of claim 35 comprising:
applying a ground voltage to one junction region and a semiconductor substrate;
applying a control voltage to the other junction region;
applying a first high voltage to a gate of a memory cell adjacent to the junction region to which the control voltage is applied; and
applying a second high voltage to a gate of a memory cell adjacent to the junction region to which the ground voltage is applied,
wherein hot electrons are injected into the charge-trapping layer of the memory cell to which the first high voltage is applied, from the channel region of the semiconductor substrate.

48. A method for operating the non-volatile memory device of claim 35 comprising:
applying a ground voltage to the first junction region, the second junction region and the semiconductor substrate;
applying a first high voltage to one gate of the memory cells; and
applying the ground voltage or a programming/erasing prevention voltage which is lower than the programming/erasing voltage, to the other gate of the memory cells,
wherein charges are injected from the channel region of the semiconductor substrate into the charge-trapping layer of the memory cell to which the programming/erasing voltage is applied, or emitted from the charge-trapping layer into the semiconductor substrate, through Fowler-Nordheim tunneling.

49. A method for operating the non-volatile memory device of claim 35 comprising:
applying a ground voltage to the first junction region, the second junction region and the semiconductor substrate; and
applying the programming/erasing voltage to the gates of the first and second memory cells simultaneously,
wherein charges are simultaneously injected from the channel region of the semiconductor substrate into the charge-trapping layers of the first and second memory cells to which the programming/erasing voltage is applied, or simultaneously emitted from the charge-trapping layers of the first and second memory cells into the semiconductor substrate, through Fowler-Nordheim tunneling.

50. A method for operating the non-volatile memory device of claim 35 comprising:
applying a ground voltage to one of the junction regions and the semiconductor substrate;
applying a first high voltage of a positive voltage to the other one of the junction regions;
applying a second high voltage of a negative voltage to the gate of the memory cell adjacent to the junction region to which the first high voltage is applied; and
applying the ground voltage to the gate of the memory cell adjacent to the junction region to which the ground voltage is applied,
wherein hot holes, which are generated through band-to-band tunneling, are injected from the junction region to which the first high voltage is applied into the charge-trapping layer of the memory cell to which the second high voltage is applied.

51. A method for operating the non-volatile memory device of claim 35 comprising:
applying a first high voltage of a positive voltage to the first and second junction regions;
applying a ground voltage to the semiconductor substrate; and
applying a second high voltage of a negative voltage to the gates of the first and second memory cells simultaneously,
wherein hot holes, which are generated from the first junction region through band-to-band tunneling, are injected into the charge-trapping layer of the first memory cell adjacent to the first junction region, and hot holes, which are generated from the second junction region through band-to-band tunneling, are injected into the charge-trapping layer of the second memory cell adjacent to the second junction region.

52. A method for operating the non-volatile memory device of claim 35 comprising:
applying a ground voltage to the first junction region, the second junction region and the semiconductor substrate;
applying a negative high voltage to one gate of the memory cells; and
applying the ground voltage to the other gate of the memory cells,
wherein holes are injected from the semiconductor substrate into the charge-trapping layer of the memory cell to which the negative voltage is applied through Fowler-Nordheim tunneling.

53. A method for operating the non-volatile memory device of claim 35 comprising:
applying a ground voltage to the first junction region, the second junction region and the semiconductor substrate; and
applying a negative high voltage to the gates of the first and second memory cells simultaneously,
wherein holes are injected from the semiconductor substrate into the charge-trapping layers of the first and second memory cells through Fowler-Nordheim tunneling.

54. A method for forming a non-volatile memory device, the method comprising:
forming a memory layer having a tunnel oxide layer, a charge-trapping layer and a blocking insulating layer stacked on a substrate in sequence;
forming a conductive layer on the memory layer;
forming spaced apart a first memory cell and a second memory cell by patterning the conductive layer and the memory layer;
forming insulating spacers on sidewalls of each memory cell, wherein the insulating spacers between the memory cells are connected to each other to form a non-charge trapping insulating layer; and
forming a first junction region on lateral side of the first memory cell and a second junction region on a lateral side of the second memory cell by performing an ion implantation process.

55. The method of claim 54, further comprising, before the forming of the insulating spacer and the non-charge trapping insulating layer, forming a third junction region in the semiconductor substrate between the memory cells, of which the depth is different from those of the first and second junction regions, by implanting impurity ions of which conductive types are identical to the conductive types of the first and second junction regions.

56. The method of claim 55, wherein the third junction region is formed shallower than the first and second junction regions.

57. The method of claim 55, wherein the third junction region is lower in doping concentration than the first and second junction regions.

58. The method of claim 54, further comprising, before the forming of the memory layer, forming an impurity diffusion layer on a surface of the semiconductor substrate by implanting an impurity ion which is opposite in conductive type to the semiconductor substrate.

59. The method of claim 54, wherein the memory layer is formed by stacking on oxide layer, a nitride layer and an oxide layer on the substrate in sequence.

60. The method of claim 54, wherein the forming of the first and second memory cells comprises:
forming a first dummy pattern and a second dummy pattern on the conductive layer;
forming spacers on sidewalls of the dummy patterns;
removing the dummy patterns;
etching the exposed conductive layer and the memory layer using the spacers as an etch mask; and
removing the spacers.

61. The method of claim 60, further comprising, before forming the dummy patterns, forming a hard mask layer on the conductive layer, wherein the hard mask layer is etched to form hard mask layer patterns after the removing of the dummy patterns and the exposed conductive layer and the memory layer are etched using the hard mask layer patterns as an etch mask.

62. The method of claim 60, wherein each of the dummy patterns is formed such that has a minimum linewidth, and the distance between neighboring dummy patterns is equal to or greater than the minimum linewidth and is equal to or less than two times the minimum linewidth, and each hard mask layer pattern is formed such that the width of each hard mask layer pattern is less than half the distance between the neighboring dummy patterns, the space between two neighboring hard mask layer patterns is less than the minimum linewidth.

63. The method of claim 54, wherein the forming the insulating spacers and the non-charge trapping insulating layer includes forming an oxide layer, and etching back the oxide layer.

64. The method of claim 55, wherein the forming the insulating spacers and the non-charge trapping insulating layer includes forming an oxide layer, and etching back the oxide layer.

65. The method of claim 57, wherein the forming the insulating spacers and the non-charge trapping insulating layer includes forming an oxide layer, and etching back the oxide layer.
